(19) United States
(12) Patent Application Publication
(10) Pub. No.: US 2026/0368511 A1
(43) Pub. Date: Nov. 19, 2026

(54) Neural Network Application-Specific Integrated Circuit

(71) Applicant: DiffLogic Inc., Dover, DE (US)

(72) Inventor: Felix Petersen, Santa Clara, CA (US)

(73) Assignee: DiffLogic Inc., Dover, DE (US)

(21) Appl. No.: 19/568,703

(22) Filed: Mar. 16, 2026

Related U.S. Application Data
(60) Provisional application No. 63/772,329, filed on Mar. 14, 2025.
(60) Provisional application No. 63/772,339, filed on Mar. 14, 2025.
(60) Provisional application No. 63/772,334, filed on Mar. 14, 2025.
(60) Provisional application No. 63/772,342, filed on Mar. 14, 2025.
(60) Provisional application No. 63/901,796, filed on Oct. 19, 2025.
(60) Provisional application No. 63/927,929, filed on Nov. 30, 2025.
(60) Provisional application No. 64/002,139, filed on Mar. 10, 2026.
(60) Provisional application No. 64/006,864, filed on Mar. 16, 2026.
(60) Provisional application No. 64/007,375, filed on Mar. 16, 2026.
(60) Provisional application No. 64/007,546, filed on Mar. 16, 2026.

(51) Int. Cl. G06N 3/065; H03K 3/037

(52) U.S. Cl. CPC G06N 3/065; H03K 3/037

(57) ABSTRACT

This disclosure describes application-specific integrated circuits (ASICs) that implement neural-network inference using non-reconfigurable physical logic circuitry. In various embodiments, machine-learned functional information is physically embodied in selections of logic functions, connections, wires, omitted connections, constants, arrangements of logic circuitry, or combinations thereof, rather than in memory-stored weights or parameters. The logic circuitry may include deep layers of sub-circuitry arranged between inputs and outputs, and may implement most of the neural-network operations directly in fixed logic. During inference, the use of machine-learned functional information may be input-dependent, such that different portions of the embodied logic contribute based on the input. The disclosed circuits may be synthesized from trained node networks and deployed as fixed-silicon implementations that provide efficient inference with low latency, reduced memory dependence, and hardware-native execution of learned functionality

### RELATED APPLICATIONS

This application claims priority to and benefit under 35 U.S.C. § 119 to U.S. Provisional Patent Application No. 63/772,329, filed on Mar. 14, 2025, titled “Extended Differentiable Logic Gate Networks” (DFL0100); U.S. Provisional Patent Application No. 64/002,139, filed on Mar. 10, 2026, titled “Logic Gate Network Systems, Methods, and Devices” (DFL0101); U.S. Provisional Patent Application No. 63/772,334, filed on Mar. 14, 2025, titled “Method for Construction and Synthesis of Efficient Feature Extractors” (DFL0300); U.S. Provisional Patent Application No. 64/006,864, filed on Mar. 16, 2026, titled “Systems and Methods for Construction and Implementation of Efficient Feature Extractors” (DFL0301); U.S. Provisional Patent Application No. 63/772,339, filed on Mar. 14, 2025, titled “Efficiency Improvements for Training Differentiable Logic Gate Networks” (DFL0400); U.S. Provisional Patent Application No. 63/772,342, filed on Mar. 14, 2025, titled “Data-based and Stochastic Logic Simplification of Logic Gate Networks” (DFL0600); U.S. Provisional Patent Application No. 64/007,375, filed on Mar. 16, 2026, titled “Data-Based, Ranking-Guided, and Stochastic Approximate Logic Optimization of Logic Gate Networks” (DFL0603); U.S. Provisional Patent Application No. 63/901,796, filed on Oct. 19, 2025, titled “Digital Neural Inference Integrated Circuit with Predominantly Latent Parameterization Circuitry” (DFL0900); U.S. Provisional Patent Application No. 63/927,929, filed on Nov. 30, 2025, titled “Training Apparatus with Integrated Circuits for Training Logic Gate Networks” (DFL1000); and U.S. Provisional Patent Application No. 64/007,546, filed on Mar. 16, 2026, titled “Neural Network Application-Specific Integrated Circuit” (DFL1200), each of which is hereby incorporated by reference in its entirety.

Various embodiments of this application also relate to, can be further understood in the context of, and/or can be combined with embodiments described in U.S. patent application Ser. No. 19/301,717, filed on Aug. 15, 2025, titled “Logic Gate Networks Generated Using Differentiable Logic Gate Models” (DFL0800); and U.S. patent application Ser. No. 19/392,098, filed on Nov. 17, 2025, titled “Digital Neural Inference Integrated Circuits with Predominantly Latent Parameterization Circuitry” (DFL0920), each of which is hereby incorporated by reference in its entirety.

### TECHNICAL FIELD

This disclosure relates to artificial intelligence hardware and integrated circuits for machine-learning inference. More particularly, this disclosure relates to application-specific integrated circuits that implement neural-network functionality using non-reconfigurable logic circuitry in which machine-learned functional information is physically embodied in logic-gate selections and connections, rather than stored in memory.

### BRIEF DESCRIPTION OF THE DRAWINGS

FIG. 1 illustrates an example accuracy-versus-gate-count comparison plot for logic gate network models, according to one embodiment.

FIGS. 2A-B illustrate example trained logic gate networks for performing inference tasks, including reinforcement learning control and image classification, according to various embodiments.

FIGS. 3A-B illustrate a comparison between Gaussian and residual initialization for a differentiable logic gate network, according to one embodiment.

FIG. 4A illustrates an example process for performing residual initialization, according to one embodiment.

FIG. 4B illustrates an example process for performing residual initialization by biasing gate-operator selection toward feedforward behavior prior to training, according to one embodiment.

FIG. 5 illustrates an example convolutional logic gate network architecture including logic gate tree convolutional blocks, OR-pooling blocks, and a classification head, according to one embodiment.

FIG. 6 illustrates an example computing system architecture for instantiating, training, and discretizing logic gate networks, according to one embodiment.

FIG. 7 illustrates an example results table comparing accuracy and gate counts for CIFAR-10 across logic gate network models and baseline models, according to one embodiment.

FIG. 8A illustrates an example results table comparing accuracy and hardware inference timing across models for CIFAR-10, according to one embodiment.

FIGS. 8B-C illustrate example results tables for MNIST, including accuracy, gate counts, hardware timing, and variability across model instances, according to one embodiment.

FIG. 9 illustrates an example application-specific integrated circuit that performs neural-network inference using deeply layered non-reconfigurably physically implemented sub-circuitry arranged between an input and an output, according to one embodiment.

FIG. 10 illustrates an example ablation results table for architectural and training choices in convolutional logic gate networks, according to one embodiment.

FIG. 11 illustrates an example plot comparing training behavior under residual initialization versus Gaussian initialization, according to one embodiment.

FIGS. 12A-B illustrates example distributions of selected logic gate operators in trained models under different initialization schemes, according to one embodiment.

FIG. 13 illustrates an example results table comparing reinforcement-learning rewards and inference latencies for a neural-network teacher and a logic gate-network student, according to one embodiment.

FIG. 14 illustrates an example process for training a node network using heterogeneous relaxations, according to one embodiment.

FIG. 15 illustrates an example process for training a node network using a first relaxation for a first set of nodes and a second relaxation for a second set of nodes, according to one embodiment.

FIG. 16 illustrates an example hyperparameter table for training and scaling logic gate network models for CIFAR-10 and MNIST, according to one embodiment.

FIG. 17 illustrates an example hardware placement of a trained logic gate network on a programmable logic device, according to one embodiment.

FIG. 18 illustrates an example plot comparing training and test accuracy between differentiable training mode and discretized inference mode, according to one embodiment.

FIG. 19 illustrates an example plot of test accuracy versus a residual-initialization hyperparameter, according to one embodiment.

FIG. 20 illustrates an example table that enumerates two-input logic operators, their corresponding real-valued relaxation formulations, and their truth tables, according to one embodiment.

### DETAILED DESCRIPTION

Machine-learning models are increasingly deployed in real-world inference settings where compute, power, latency, determinism, and verifiability matter as much as raw accuracy. For example, inference models may be deployed on embedded devices, industrial control systems, cyber-physical systems, and other environments with strict timing constraints. In such settings, even modest increases in model latency can reduce control bandwidth, limit achievable performance, and/or constrain the complexity of the model that can be used. In reinforcement-learning (“RL”) deployments, these constraints can be particularly acute because decisions may be made at high frequency and directly coupled to physical processes. For example, real-time reinforcement-learning agents have been explored for controlling complex systems such as tokamaks, fiber-laser systems, and network systems, where low latency can limit agent expressivity and overall system performance. In at least some reported tokamak-control contexts, latency budgets on the order of tens of microseconds (e.g., 50 μs) have been identified as constraining agent expressivity and performance.

Conventional deep neural networks (e.g., convolutional neural networks (“CNNs”), transformer-based architectures, and the like) are typically parameterized by real-valued weights and biases and rely on matrix multiplications and other dense numeric operations. These operations can impose substantial inference cost, both in computation and in memory traffic (e.g., repeatedly fetching weights and intermediate tensors). Specialized accelerators can improve throughput, but practical deployments often remain constrained by power budgets, memory bandwidth, thermal limits, and/or end-to-end latency. Moreover, in some applications, including safety-critical or regulated applications, there is growing interest in models that are more interpretable and/or more amenable to verification, auditing, and deterministic execution.

As a result, a variety of approaches have been explored to reduce inference cost, including model quantization, binary-weight networks, binary activations, and structured sparsity. In the broader class of “binary neural networks,” for example, an abstraction based on neural network layers is retained, but representations are constrained and/or quantized to reduce compute and improve hardware efficiency. However, even when weights and activations are quantized, many systems still rely on neural-network abstractions that are ultimately compiled, translated, or otherwise mapped into executable logic, thereby imposing additional complexity and overhead. In contrast, another approach is to represent an inference model directly in terms of logic (e.g., as a network of logic gates) and optimize the logic itself, thereby directly targeting the computational substrate of digital hardware. In some embodiments, the learned inference function is embodied directly in non-reconfigurable logic selections and hardwired interconnections, rather than in memory-stored weights or addressed memory contents. Thus, inference may be performed by propagating signals through the logic itself, instead of repeatedly retrieving learned values from memory during a main inference data path.

Logic gate networks may be viewed as networks of nodes, where each node implements a Boolean operator such as AND, NAND, OR, NOR, XOR, XNOR, and/or related logic functions. Logic gate networks (also referred to as logical circuits or binary circuits) are the type of representation used at a fundamental abstraction level to implement digital computation in hardware. The function computed by a logic gate network depends on the connections among the nodes and on the logic operation selected at each node. From a deployment perspective, logic gate networks can be attractive because they can be implemented directly as logic circuitry. When an inference model is represented as a logic gate network (or can be discretized into one), inference can be performed using only logic gate operations, enabling highly efficient, deterministic execution on logic-based hardware such as CPUs, FPGAs, and ASICs. In some implementations, the absence of large weight fetches and dense floating-point operations can enable extremely low-latency inference; for example, logic gate inference may be executed on hardware with latency on the order of nanoseconds (or less) and, in some cases, may enable evaluation of an entire model within a single clock cycle depending on architecture and target device constraints. In some embodiments, a deployed hardware implementation of such a node network includes non-reconfigurably physically implemented sub-circuitry having at least 1000 physical logic gates and multiple layers between an input and an output. In some embodiments, the sub-circuitry implements most neural-network operations directly in fixed logic rather than in memory-backed or reconfigurable resources. In some embodiments, sub-circuitry implements some or most of the neural network operations without a separation between learned information and the operations, but instead, wherein the operations are the learned information, alleviating the need to exclusively or primarily store learned information in memories and retrieve it from respective memories.

However, optimizing a logic gate network for a machine-learning task is generally challenging. In its native form, a logic gate network involves discrete gate choices and discrete Boolean computations. Selecting connections and selecting a gate type for each node is naturally a combinatorial optimization problem. While combinatorial search or heuristic synthesis can be effective for some circuit-design tasks, direct combinatorial optimization becomes infeasible when a machine-learning problem demands extremely large models (e.g., models having millions of parameters or gates). In addition, conventional gradient-based training is not directly applicable because discrete logic operations and discrete gate-selection decisions are not differentiable.

To enable scalable training, differentiable relaxations of logic gate networks have been proposed that relax Boolean logic operations into differentiable, real-valued computations and replace the discrete choice of logic operator at each node with a differentiable parameterization, such as a probability distribution over candidate operators. This enables the use of gradient-based optimization to train networks that are ultimately intended to be discretized into hard logic for inference.

In one illustrative approach, a differentiable logic gate node may maintain a set of learnable parameters that define a categorical distribution over a predefined set of logic gate operators (e.g., 16 two-input Boolean operators). A “soft” node output can then be computed as a weighted combination (e.g., an expectation) of the outputs of the candidate logic functions, where the weights are determined by the learned distribution (e.g., via a softmax over the learnable parameters). As training progresses, the learned distributions may sharpen, and training may converge toward concrete logic gate choices. The resulting trained model can then be discretized by selecting, for each node, the operator with the highest learned probability, yielding a hard logic gate network suitable for deployment as logic circuitry. In some embodiments, after discretization, the learned function is physically embodied in selected logic functions and selected connections of deployed hardware rather than in a stored-parameter memory. In this sense, the resulting circuitry embodies machine-learned functional information in the physical structure of the logic participating in inference.

In some embodiments, during training, a node configurable to implement a discrete operation in a discretized (deployment) form is represented as a trainable form that combines the outputs of multiple candidate operations in a differentiable manner. For example, a two-input node receiving inputs a₁ and a₂ (which may be real-valued relaxations in [0,1] during training) may be associated with candidate operations {gᵢ}(e.g., candidate logic gate operators, candidate node functions, or candidate lookup-table entries, as described in detail herein), and a parameter vector z (e.g., unnormalized scores, logits, etc.) that is mapped to coefficients or selection weights used to combine the outputs of the candidates. In some embodiments, the process may include selecting between and/or learning connections (e.g., wires). For example, some differentiable logic gate nodes with two inputs may be restricted to two options, each option being a respective direct wire connection (e.g., selecting between “Wire A” and “Wire B”). In another illustrative example, an eight-input differentiable logic gate node may be restricted to eight options, each option being a respective direct wire connection (e.g., selecting one of Wires A, B, C, D, E, F, G, or H). In such embodiments, at least some nodes of the network correspond to logic gate operators that actively rely on two or more inputs (e.g., AND, NOR, OR, XOR, etc.).

In some embodiments, a “convex combination” (e.g., an expectation or weighted average) is used to compute a differentiable node output. For example, a node output f_{z}(a₁, a₂) may be expressed as:

$${f}_{z} ( {a}_{1} , {a}_{2} ) = {𝔼}_{i ∼ S ( z ) , {A}_{1} ∼ ℬ ( {a}_{1} ) , {A}_{2} ∼ ℬ ( {a}_{2} )} [ {g}_{i} ( {A}_{1} , {A}_{2} ) ] = {\sum }_{i = 0}^{15} \frac{exp ( {z}_{i} )}{{\sum }_{j} exp ( {z}_{j} )} \cdot {g}_{i} ( {a}_{1} , {a}_{2} )$$

In the equation above, S(z) denotes a distribution over the candidate operations derived from z, and B(a) denotes a Bernoulli distribution parameterized by a. Alternatively, or in addition to the convex combination above, some embodiments compute the differentiable node output using an “exponential combination” (e.g., a product form), for example:

$${f}_{z} ( {a}_{1} , {a}_{2} ) = {\prod }_{i = 0}^{15} {g}_{i} {( {a}_{1} , {a}_{2} )}^{\frac{exp ( {z}_{i} )}{{\sum }_{j} exp ( {z}_{j} )}}$$

In some embodiments, such an exponential combination provides a differentiable mechanism to emphasize or de-emphasize candidate operations while maintaining compatibility with operator-selection parameterizations. Alternatively, or in addition, some embodiments use alternative mappings from the zi values (or other trainable parameters) to coefficients pᵢ. In such embodiments, the coefficients pᵢ may be derived using any of a wide variety of suitable mappings, including those with nonnegative weights, normalized weights, sparse weights, temperature-scaled weights, or other coefficient structures. Using such coefficients pᵢ, the differentiable node output may be computed using, for example:

$${f}_{z} ( {a}_{1} , {a}_{2} ) = {\prod }_{i = 0}^{15} {g}_{i} {( {a}_{1} , {a}_{2} )}^{{p}_{i}} , or$$

$${f}_{z} ( {a}_{1} , {a}_{2} ) = {\sum }_{i = 0}^{15} {p}_{i} \cdot {g}_{i} ( {a}_{1} , {a}_{2} ) .$$

In various embodiments, the coefficients pᵢ are computed from trainable parameters using mappings including, but not limited to, softmax mappings, sigmoidal mappings, bounded mappings, normalized exponential mappings, thresholded mappings, learned mappings, and/or other coefficient-generating functions. The node output may be computed using one or more of the foregoing combination forms. After training, the node network may be discretized such that, for at least some nodes, a single candidate operation is selected for deployment (e.g., by applying a discretization rule that selects a candidate operation associated with a largest coefficient, a largest probability, or a largest score), thereby producing a fixed representation in which the deployed node output is computed using the selected discrete operation rather than a mixture.

Although the examples above are written for a two-input node with sixteen candidate operations (indexed I=0 to 15), in various embodiments, the candidate operation set may include fewer than sixteen options, more than sixteen options, and/or operations with more than two inputs. For example, in some embodiments, a node corresponds to a k-input operation and is configurable to implement, in a discretized form, any of a plurality of k-input Boolean functions and/or lookup-table-defined functions. These embodiments are compatible with the training, residual initialization, discretization, and deployment techniques described throughout this disclosure.

Any number of candidate operations may be available in a particular embodiment, and more or fewer parameters may be used to specify the number of candidate operations. For example, in various embodiments, the trainable form used during training may be parameterized in any suitable manner, and the number of trainable parameters associated with a node need not equal the number of discrete operations that the node may implement in a discretized form. For example, although a two-input node may be discretizable to any of sixteen possible functions, the trainable form may be implemented using (i) a set of operator-selection parameters (e.g., scores or logits) that define a selectable distribution over the sixteen functions, and/or (ii) a set of operator-selection parameters comprising four trainable values corresponding to the four possible two-input patterns (e.g., 00, 01, 10, and 11), such that discretizing the four values yields a 4-bit table and thereby selects one of the sixteen possible functions. More generally, for a node having k inputs, the trainable form may comprise a parameterization that, upon discretization, defines a discrete mapping for the node (e.g., a lookup table with 2\hat{ }k) entries and thus one of 2\hat{ }(2\hat{ }k) possible discrete functions), and the trainable form may be over-parameterized or under-parameterized relative to the number of discrete options while still supporting optimization and later discretization. Accordingly, regardless of the particular parameterization, the node's trainable computation may be expressed as a function of the node inputs and a parameter set, as reflected in the generalized expressions below:

f_{z}(a₁,a₂)=g(a₁,a₂,p), or with a greater number of inputs, as follows:

f_{z}(a₁,a₂, . . . aₖ)=g(a₁,a₂, . . . aₖ,p)

In reinforcement-learning and control tasks, inference latency can be a primary performance constraint. In many reinforcement-learning deployments, an agent repeatedly observes a state (or observation) and produces an action. When a control loop must execute at high frequency, the agent's inference latency can limit the policy's complexity and the achievable responsiveness. As noted above, real-time applications such as tokamak control, fiber-laser control, and network control have motivated interest in inference latencies on the order of microseconds and nanoseconds.

Differentiable logic gate networks can be used as reinforcement-learning agents (or as components of reinforcement-learning agents) because, after discretization, the resulting models can be executed as pure logic. This can potentially allow substantially lower latency than conventional neural-network inference, particularly when deployed on programmable logic or dedicated hardware.

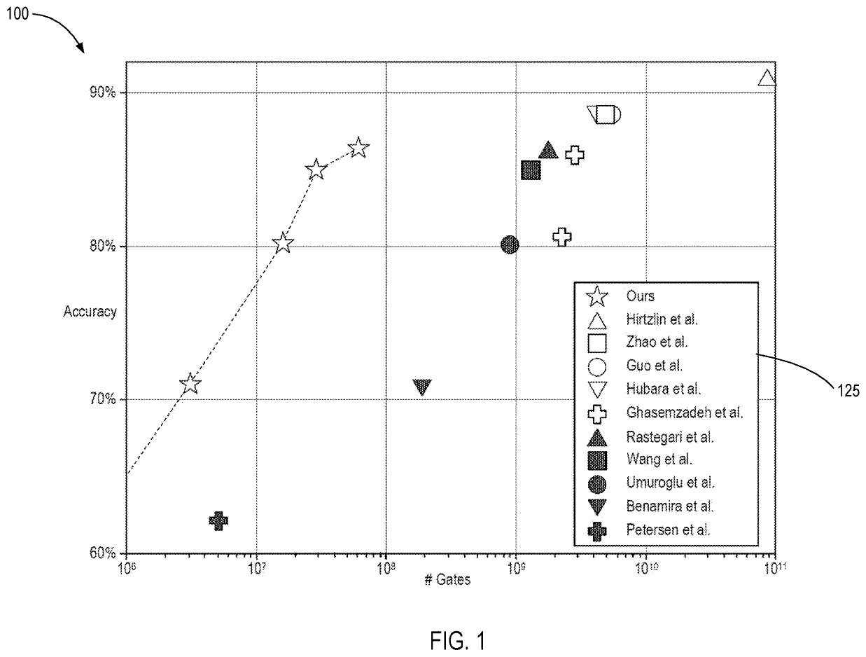

FIG. 1 shows a plot 100 of gate count versus accuracy for the CIFAR-10 dataset from various sources identified in the legend 125, highlighting the broader challenge of achieving high accuracy at low logic cost. As illustrated, the gate-count axis can span multiple orders of magnitude (e.g., on a log scale), demonstrating that logic cost is often a key driver of the feasibility of hardware deployment. Thus, there remains a continuing need for training and architecture techniques that improve the accuracy-per-gate tradeoff for logic-based inference models. As models are scaled in depth to increase expressivity, training stability can degrade. Conventional deep neural networks often use techniques such as residual connections to preserve information flow and mitigate vanishing gradients as depth increases. In contrast, in logic gate and differentiable logic gate networks, architectural and operational differences can make the direct transfer of certain deep-learning techniques non-trivial. In particular, while residual additions are widely used in conventional networks, direct additive residual pathways are generally not native to purely logical computation, and deeper networks may be more susceptible to instability if intermediate representations “wash out” toward ambiguous values (e.g., toward 0.5 in a probabilistic relaxation). Moreover, when a differentiable relaxation is used, gradients can decay significantly across many logic layers, inhibiting learning in deep architectures.

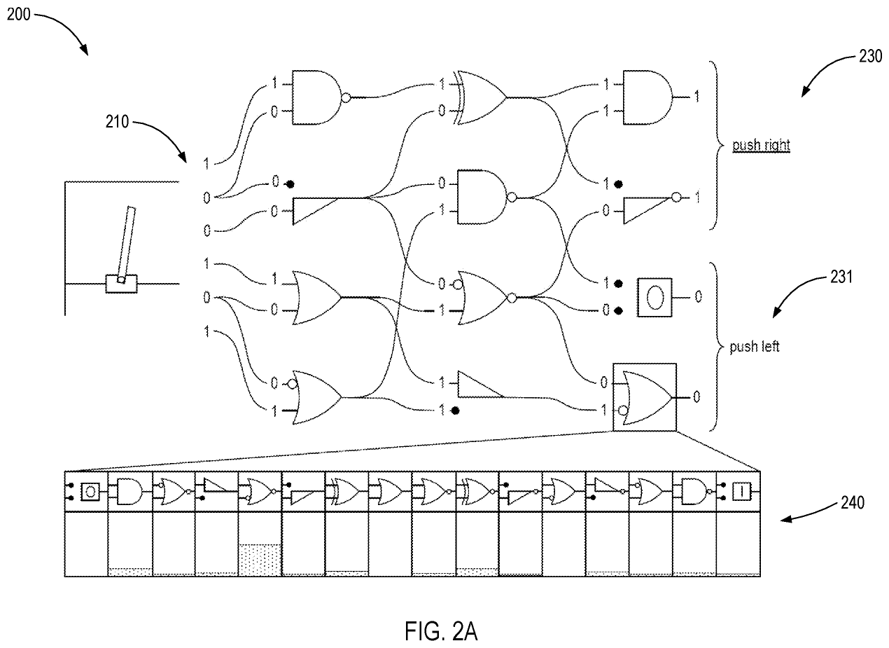

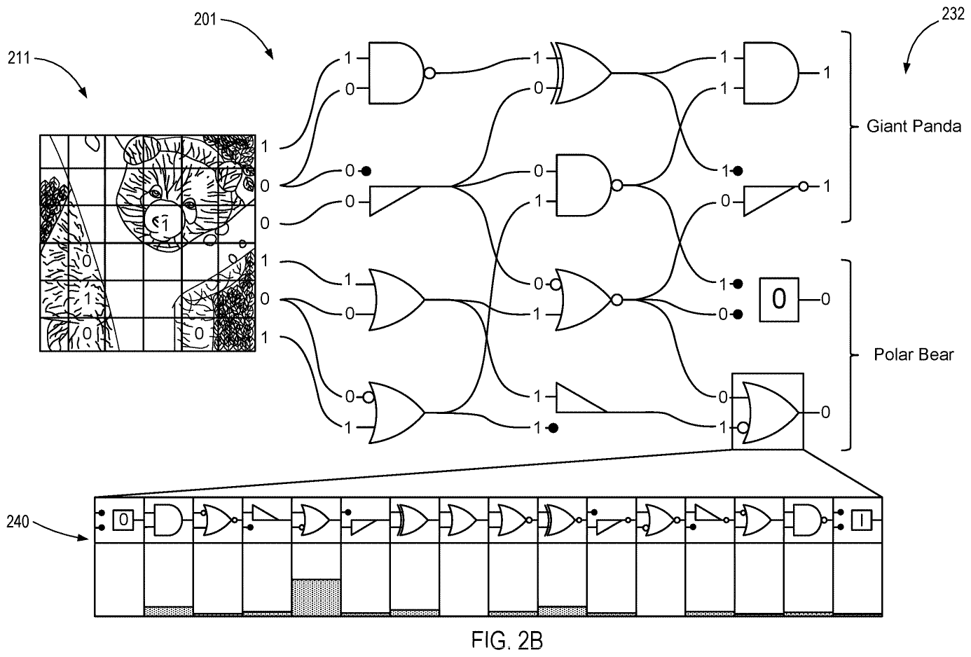

FIG. 2A illustrates a logic gate network 200 that maps a set of inputs 210 to possible action outputs 230 and 231, highlighting how a policy can be realized as combinational logic rather than as a dense numeric computation. Nevertheless, while logic gate based inference can reduce runtime cost, training and scaling differentiable logic gate networks introduce their own challenges. These challenges include architectural limitations, optimization stability, and the difficulty of achieving high accuracy at a given logic cost.

Computer-vision tasks such as image classification, object recognition, and related perception problems have historically benefited from architectures that exploit spatial structure, such as convolution and pooling. Conventional CNNs rely on local receptive fields, structured parameter sharing, and pooling operations to efficiently capture translational invariance and local spatial patterns.

By contrast, the differentiable logic gate networks originally proposed typically use randomly selected connectivity. Because logic gates, in some implementations, are inherently two-input operators, the resulting logic gate networks are sparse and cannot form fully connected layers in the same way that dense neural networks can. In many differentiable logic gate network formulations, a node connectivity option is selected at random from the available options 240 and held fixed during training, and the learning problem focuses on selecting a gate operator for each node given the fixed wiring. This random connectivity can work for some tasks but becomes problematic when the input data has strong inherent structure, such as the spatial structure of images. Such limitations have been observed in reported results. For example, a noted limitation of randomly connected logic gate networks is their inability to learn spatial relations in images, which has been reported to limit performance on datasets such as CIFAR-10 to relatively low accuracy (e.g., around 62% in certain reported contexts).

FIG. 2B illustrates an example of a randomly connected logic gate network architecture 201. In the illustrated embodiment, an input representation 211 (e.g., a binarized or discretized input patch corresponding to a portion of an image or other structured input) provides input values to a plurality of interconnected logic gate nodes of the architecture 201. The nodes are connected in a non-convolutional, non-parameter-shared manner (i.e., with connectivity that is not constrained to local receptive fields or structured weight sharing), and the resulting network produces one or more outputs 232, which in the illustrated example correspond to classification outputs (e.g., a “Giant Panda” output and a “Polar Bear” output). In some embodiments, each node of the architecture 201 is represented as a selectable logic gate chosen from an available set of logic gate choices 240, and during training, the node's selected operation (or a trainable representation thereof) is learned (e.g., by learning gate-choice distributions and/or other trainable parameters that are later discretized into fixed per-node gate selections).

In practice, while the randomly connected architecture 201 can be effective for some tasks, such architectures may be less able to incorporate inductive biases and architectural components that are well suited to structured domains (including, for example, local receptive fields, parameter sharing, and pooling), while maintaining the desirable deployment properties of logic-based inference. In many practical deployments, it is not sufficient to merely execute inference as logic; rather, it is important to achieve high model quality at an acceptable cost of logic. Logic cost can be measured in various ways (e.g., total number of logic operators, total number of gates, depth, routing complexity, area, or power). In at least some contexts, the number of logic gates (or binary operations) can serve as an approximate proxy for hardware cost, because gate counts relate to chip area and can correlate with transistor count for ASIC implementations or resource utilization (occupancy) for FPGA implementations.

Accordingly, there remains a need for training techniques and initialization approaches that allow differentiable logic gate networks to scale in depth while preserving trainability, maintaining stable information flow, and enabling convergence to useful discrete logic after discretization. In view of the foregoing, there is a continuing need for improved systems, methods, and computer-readable media that facilitate practical training and deployment of logic gate-based machine-learning models. By way of example and without limitation, desirable improvements include: (i) achieving improved model accuracy for a given logic cost (e.g., gate count), (ii) improving the ability of logic gate networks to model structured domains such as images and other spatial/temporal signals, (iii) providing pooling- and convolution-like architectural components compatible with logic-based computation, (iv) improving optimization stability and trainability, particularly for deeper networks, and (v) enabling efficient, deterministic, low-latency deployment of trained models as logic circuitry on hardware such as FPGAs and ASICs. These needs are particularly salient in real-time decision-making settings such as reinforcement learning and control, where inference latency may directly limit achievable system performance.

In various embodiments, the present disclosure relates to training and deploying machine-learning models implemented using logic-gate-based computation. In some embodiments, a logic gate network comprises a plurality of interconnected nodes configured to receive inputs and produce outputs for an inference task, where one or more nodes are associated with a predefined set of potential logic gate operators. In some embodiments, the logic gate network is trained in a differentiable manner by parameterizing at least some nodes with differentiable parameters that define operator-selection probability distributions over the predefined set, thereby enabling gradient-based optimization, while further enabling generation of a fixed logic gate network after training by identifying discrete logic gate operators for respective nodes based on the learned differentiable parameters.

While differentiable logic gate networks can provide advantages in inference efficiency, compactness, and hardware implementability, practical deployment may benefit from improvements that enhance trainability, scalability to structured data, and computational efficiency of both forward propagation and backpropagation. Accordingly, in various embodiments, the present disclosure provides multiple complementary techniques directed to these challenges, including, without limitation, student-teacher supervision to reduce training cost and/or improve resulting model quality, convolutional architectures in which convolution kernels are implemented as tree-structured logic gate sub-networks with parameter sharing across kernel placements, pooling operations expressed in a logic-compatible manner using min/max relaxation operations and associated gradient-propagation techniques, and residual-style initialization approaches that bias nodes toward feedforward behavior at initialization to improve signal and gradient flow in deeper architectures.

The foregoing techniques may be implemented independently or in any combination, depending on the target task, compute platform, and performance characteristics. For example, a convolutional logic gate tree network may be trained using residual initialization and logic-compatible pooling, and may further be supervised using teacher-generated outputs; after training, the differentiable network may be discretized to yield a fixed logic gate network representable as a logical expression and implementable in software and/or in logic circuitry (including programmable logic and/or application-specific integrated circuits). The following paragraphs summarize non-limiting embodiments relating to each of these aspects.

In some embodiments, the present disclosure additionally pertains to integrated circuits in which machine-learned functional information is physically embodied directly in non-reconfigurable logic circuitry, rather than being stored as values in a memory and read during inference. For example, the learned function may be embodied in selections of physical logic gates, selections of connections (e.g., wires or traces) between the logic gates, omissions of connections/wires, arrangements of logic structures, selections of constants, and/or other fixed structural choices that participate directly in an inference data path. In such embodiments, inference is performed by propagating signals through the physically implemented logic circuitry itself. As such, the learned information is not represented merely as memory contents that are addressed and read out from a memory array.

For example, an application-specific integrated circuit (ASIC) may include logic circuitry that is an implementation of a neural network (e.g., a neural network that has already been completely or at least substantially trained). In some embodiments, the logic circuitry includes a sub-circuit or sub-circuitry that non-reconfigurably physically implements all or substantially all of the neural network. In some embodiments, the logic circuitry includes a sub-circuit or sub-circuitry that is non-reconfigurably physically a part of the neural network. This “physically embodied” approach is distinct from memory-centric approaches, including those in which learned values are stored in read-only memory, mask ROM, or other addressable memory structures and then supplied to generic compute logic during inference. In a mask-programmed memory approach, the learned information remains encoded as memory contents to be retrieved by addressing circuitry, decoders, bitlines, and/or sense circuitry. By contrast, in various embodiments described herein, the learned function is embodied in the structure of the logic that directly participates in the inference computation. Stated differently, the learned information is encoded in logic selections and connections that form the computational path from input to output (e.g., the choice, placement, routing, and/or wiring connections between logic gates), rather than in a memory that stores learned values for later retrieval.

In some embodiments, a node network comprises at least two node subsets treated differently during training. For example, a first set of nodes may comprise learnable nodes parameterized by differentiable parameters associated with respective predefined sets of potential logic gate operators, while a second set of nodes may comprise nodes corresponding to respective predefined logic gate operators. In some embodiments, outputs of nodes in the first set are computed using a first relaxation, and outputs of nodes in the second set are computed using a second relaxation different from the first relaxation. In some embodiments, the second set of nodes is used to impose structural inductive bias in the node network, including, by way of example and without limitation, spatial pooling in convolutional logic gate networks, temporal connections in sequential logic gate networks, and/or gates configured to combine an activation from one layer with a residual activation from a different layer. In some embodiments, after training, a fixed logic gate network is generated based on (i) the predefined logic gate operators of the second set of nodes and (ii) selected logic gate operators for at least some nodes of the first set based on the differentiable parameters thereof.

In some embodiments, systems, methods, and computer-readable media are provided for training and deploying logic gate networks with student-teacher supervision. Training differentiable logic gate networks may be slower than training conventional neural networks; therefore, distillation from a teacher model may be used to reduce training costs and/or improve the quality of the resulting student model.

In some embodiments, a teacher model (e.g., a conventionally trained neural network, including a reinforcement-learning policy network) is trained to perform a machine-learning task and to generate, for each input, a teacher output (e.g., a probability distribution over classes or actions). A training corpus is formed that includes input observations and corresponding teacher outputs. A differentiable logic gate network is then trained as a student by minimizing a divergence measure between the student outputs and the teacher outputs. For example, the system may use a Kullback-Leibler divergence approach to measure the divergence between the student and teacher outputs. The student-teacher approach transfers the teacher model's behavior into a logic-gate-based student model.

In some embodiments, teacher supervision is applied at the output-representation level suitable for logic gate networks. For example, classification may be represented via class scores formed by aggregating outputs of groups of output gates, and temperature scaling may be applied to logits or class scores, including in implementations where the teacher supervises at the class-score level. In various embodiments, the logic gate network comprises a set of group sum operations, which may be per-group popcount operations, bit counters, or adder circuits. For example, each group may correspond to one class or one output. In various embodiments, the group sum operation is performed via a real-valued summation during training, corresponding to a population counter or bit counter that is used in the fixed circuit after training. In some embodiments, approximate bit counters or approximate adders are used. This can provide the benefit of reducing the inference cost while maintaining sufficiently high quality.

In some embodiments, after training, the differentiable logic gate network is discretized (e.g., by selecting a logic gate operator for each node based on learned probabilities) to yield a hard, fixed logic gate network. The fixed logic gate network may be synthesized and deployed as logic circuitry, including on hardware such as an FPGA or ASIC, to enable efficient inference and/or low-latency inference In some embodiments, the deployed hardware performs inference without reading learned weights from a memory during evaluation of the fixed logic network, because the learned functionality is embodied directly in the selected node functions and their interconnections. This distinction may be important, for example, in ASIC implementations in which the machine-learned function is realized in fixed sub-circuitry rather than in mask-programmed or other addressed memory structures. In some embodiments, the deployed hardware performs inference, in part, substantially without reading learned weights from a memory during evaluation of a sub-circuitry of the fixed logic network, which may be enabled by learned functionality being embodied directly in the selected node functions and their interconnections.

In some embodiments, the training corpus may be collected in multiple ways, including by collecting teacher-labeled observations from the beginning, from a later time, or as a mixture. In some embodiments, the current logic gate network is used as an agent to obtain observations while a teacher provides feedback and/or a secondary teacher model is trained on residuals of the logic gate network. In some embodiments, real-valued inputs are encoded into binary vectors prior to logic-gate evaluation, for example, via thermometer encoding with quantiles as thresholds.

In various embodiments, the present disclosure provides systems and methods for implementing convolutional logic gate networks by convolving activations with logic gate trees. In some embodiments, each convolution kernel is realized as a logic gate tree (e.g., a complete binary tree of depth d) whose leaves are selected from a predefined receptive field across one or more channels, and whose internal nodes apply logic gate operations. By using tree-structured kernels and sharing node parameterizations across kernel placements, the disclosed approaches extend the convolutional paradigm, including spatial equivariance via parameter sharing, to logic gate networks, while improving expressivity relative to single-gate kernels and efficiency by reducing memory accesses and improving the locality of operations. In some embodiments, after training and discretization, the resulting physical logic may not be arranged as periodically repeating functional blocks (e.g., periodically repeating arithmetic blocks), but may instead exhibit an aperiodic block pattern across a substantial fraction of physical logic gates due to learned gate selections and learned interconnections. Such aperiodic structure may itself embody machine-learned functional information of the deployed circuit, if it was learned. It is appreciated that logic gates physically arranged in rows and/or columns do not imply a periodically repeating block arrangement; instead, the type of gates, their wires, and/or their composition are considered to identify periodically repeating block arrangements. In some embodiments, because the learned function is carried predominantly by selected logic operations and selected interconnections, no more than a small fraction of the sub-circuitry (e.g., no more than about 5%) comprises adder circuitry, in contrast to other types of neural network circuitry.

In some examples, a system includes one or more processors and a memory storing instructions that, when executed, cause the system to instantiate a convolutional logic gate tree network in which each logic gate node is parameterized by a set of differentiable parameters corresponding to a respective set of candidate logic operators (e.g., AND, OR, NAND, NOR, XOR, XNOR, constants, inverters, and/or direct connections), each convolution kernel comprises a tree of such logic gate nodes, and the differentiable parameters for at least some nodes are shared among multiple kernel placements of the convolution. In some embodiments, the system trains the network by forward propagating training inputs through differentiable relaxations of the candidate logic operators, evaluating a loss with respect to target outputs, and updating the differentiable parameters using gradient-based optimization, and defines a fixed convolutional logic gate tree network after training by selecting a single logic operator for each respective node based on the updated differentiable parameters.

In some embodiments, a computer-implemented method includes performing a convolution over an activation tensor. For example, for each kernel placement, the system may select a set of input activations from a receptive field as the leaves of a logic gate tree, compute the outputs of internal tree nodes based on corresponding logic gate operations, and produce a kernel output for the placement from the root node of the tree. In some embodiments, the method further includes using pooling operations compatible with logic, such as logical OR pooling (e.g., via a maximum t-conorm relaxation), and/or improving trainability of deep convolutional logic gate tree networks using residual initializations that bias one or more nodes toward direct connections (e.g., wire-like behavior) at initialization while allowing training to replace such behavior with other learned logic operations as needed.

In some embodiments, a non-transitory computer-readable medium stores instructions that, when executed by one or more processors, cause performance of any of the foregoing operations, including training a convolutional logic gate tree network and defining a fixed logic gate network after training. In some embodiments, the fixed network is stored as data defining a logical expression and/or is implemented in programmable logic (e.g., an FPGA) or synthesized into an application-specific integrated circuit (ASIC), thereby enabling efficient deployment of the convolutional logic gate tree network for inference tasks such as image recognition, language processing, and other machine learning inference tasks. In some embodiments, only a subset of the machine-learned functional information embodied in the deployed circuitry is affectively used (i.e., it affects the output) during any given inference cycle, depending on the applied input and the corresponding selected signal path. Thus, affective use of machine-learned functional information may be input-dependent and may be measured, in some embodiments, on a per-cycle basis. Further, utilization of machine-learned functional information may be measured on a per-switching-event basis.

In differentiable logic gate networks, a logic gate operation may be represented by a differentiable parameterization over a set of discrete logic gate choices (e.g., via a softmax over gate options). Conventional random initialization of such parameters can lead to “washed out” initial distributions over gate choices, which in turn can cause activations to rapidly converge toward intermediate values and can exacerbate vanishing gradients as network depth increases. While residual connections are commonly used in conventional neural networks to preserve information flow in deep architectures, direct additive residual connections are generally not available when operating purely in logic.

To address these issues, residual initialization techniques may be utilized in which one or more learnable logic-gate nodes (and in some embodiments, substantially all learnable logic-gate nodes in one or more layers, blocks, or stages) are initialized to behave primarily as a feedforwarding logic gate, such as a direct-connection (wire-like) operator or an inverter operator. In some embodiments, this is implemented by initializing differentiable parameters of a node (e.g., a vector of unnormalized scores mapped to a categorical distribution via softmax) so that an initial operator-selection probability distribution assigns a dominant initial probability to a selected feedforward operator while assigning smaller probabilities to other candidate operators in the predefined set. This residual initialization provides an information-preserving pathway through depth while remaining fully learnable, such that, during iterative training, the differentiable parameters can be updated to make a non-feedforward operator (e.g., AND, OR, XOR, NAND, or NOR) more probable, thereby improving task performance. In various embodiments, this residual initialization approach facilitates training of node networks spanning a wide range of depths, including networks that have at least 7, 15, 23, 50, 100, 250, or more than 1000 layers between an input and an output, depending on the architecture and counting convention used. As used herein, the phrase “between an input and an output” may refer to any single path in a selected sub-circuitry. The phrase “between all inputs and all outputs” may refer to all paths in a selected sub-circuitry. When counting “between all inputs and all outputs”, the outputs may be identified in a definition of the sub-circuitry, and intermediate incoming and outgoing wires not identified among the inputs and outputs may not be counted as inputs nor outputs, respectively. In some embodiments, the resulting trained networks are discretized and implemented as ASIC sub-circuitry having corresponding physical logic depth.

Residual initialization can provide a residual-like information pathway in a differentiable logic gate network without requiring hard-wired residual adders or additional residual logic gates. In practice, the residual initialization may preserve information flow and reduce gradient decay in deeper networks during the early stages of training. As training progresses, gates that do not benefit from remaining feedforward connections may be learned to perform other logic operations. Thus, in various embodiments, residual initialization functions as a differentiable analogue to residual connections while remaining compatible with logic gate-based computation and subsequent discretization.

In some embodiments, residual initialization is used in conjunction with training workflows that produce discrete logic gate networks for inference, including architectures employing logic gate trees, convolutional application of such trees, and pooling operations expressed through logic. In some embodiments, after training, gates that remain trivial feedforward choices may be simplified during synthesis, which can reduce circuit complexity (e.g., because feedforward gates may correspond to wiring rather than additional active logic), thereby improving efficiency for hardware implementations (including, but not limited to, FPGA or ASIC implementations).

As used herein, the terms “logic gate network,” “logic gate neural network,” and “differentiable logic gate network” generally refer to a computational model comprising a plurality of interconnected nodes (also referred to as neurons, units, or gates) arranged in one or more layers and/or other topologies (e.g., trees, directed acyclic graphs, or recurrent topologies). Each node may be configured to compute a node output from one or more node inputs using at least one logic gate operator. A “logic gate operator” is not limited to a strict Boolean operator (e.g., AND, OR, XOR, NAND, NOR) and may include constants (e.g., TRUE, FALSE), pass-through or direct-connection operators (e.g., outputting one of the inputs), inverter operators, and/or multi-input operators that receive three or more inputs. In some embodiments, during training, one or more logic gate operators are implemented using differentiable and/or continuous relaxations (e.g., fuzzy-logic and/or t-norm-based relaxations or t-conorm-based relaxations) such that node outputs are real-valued (e.g., within [0,1]) and gradients can be computed with respect to trainable parameters. “Differentiable parameters” may include any values usable to select and/or blend among candidate operators (e.g., logits, unnormalized scores, weights, probabilities, temperatures, and/or other parameters) and may define an operator-selection probability distribution (e.g., a categorical distribution derived via a softmax or other mapping to a simplex). In various embodiments, differentiable parameters refer to those parameters for which a gradient is computed via backpropagation. The gradient may be an exact gradient or an approximate gradient, and the gradient may be used in a gradient-based optimization algorithm. “Discretizing,” “hardening,” or “generating a fixed logic gate network” includes any technique for selecting one or more discrete operators per node (e.g., selecting a mode/argmax operator, sampling, thresholding, pruning, and/or synthesis-based simplification), such that the resulting network can be represented as a logic expression, netlist (e.g., a gate-level netlist), circuit description, hardware description language (HDL), or other fixed representation.

As used herein, a “physical logic gate” refers to a physically implemented logic element or cell of a hardware realization of a node network. Examples of physically implemented logic elements include, but are not limited to, combinational logic gates, configured lookup-table logic elements, multiplexers, and other logic cells that participate directly in forming an output from one or more inputs in a deployed hardware implementation. As used herein, “machine-learned functional information” refers to an amount of learned functional information of a trained machine-learning model, such as a trained neural network, that is sufficient to specify the learned input-output functionality of the model for an inference task. In the context of a deployed ASIC implementing a neural network in fixed logic, machine-learned functional information as well as machine-learnable functional information is not limited to information that can be practically reconstructed solely from the physical gates of the ASIC itself, and does not require that the ASIC, by itself, preserve or permit recovery of the entirety of all information that may have existed at any earlier training, optimization, or implementation stage.

In various embodiments, the “sub-circuitry” referenced herein may comprise less than all of the logic circuitry implementing a neural network. For example, the sub-circuitry of the logic circuitry on an ASIC may correspond to a selected component, portion, region, path, stage, block, subset of layers, subset of channels, subset of node operations, or another proper subset of the overall neural network implementation. For example, a neural network implemented on an ASIC may include a first sub-circuitry that embodies machine-learned functional information in non-reconfigurable physical logic gates and interconnections. In addition to the first sub-circuitry, the ASIC may additionally include one or more of input/output circuitry, clocking circuitry, control circuitry, synchronization circuitry, interface circuitry, buffering, sequential storage elements, arithmetic circuitry, and/or other supporting circuitry elements or components. In some embodiments, the ASIC may include a second sub-circuitry in addition to the first sub-circuitry. Accordingly, references herein to a sub-circuitry having a specified number of physical logic gates, layers, bit density, aperiodic structure, adder percentage, or other characteristic do not require that the entire neural-network implementation (e.g., the complete logic circuitry and/or complete ASIC fabrication) satisfy that characteristic or specification, unless explicitly stated otherwise.

In some instances, the phrase or term “machine-learnable functional information” is used as a unifying or encompassing term to refer to information capacity associated with trained parameters, trainable parameters, differentiable parameters, operator-selection parameters, operator-selection probability distributions, selected node functions, selected logic-gate operators, selected truth-table or lookup-table contents, selected constants, selected interconnections, and/or other learned or learnable functional choices that determine how a trained model transforms an input into an output during inference. In some instances, the phrase or term “machine-learned functional information” is used as a unifying or encompassing term to refer to learned information associated with trained parameters, differentiable parameters, operator-selection parameters, operator-selection probability distributions, selected node functions, selected logic-gate operators, selected truth-table or lookup-table contents, selected constants, selected interconnections, and/or other learned functional choices that determine how a trained model transforms an input into an output during inference. Examples of many types of machine-learnable functional information and machine-learned functional information are included and described in the applications previously incorporated by reference. In various embodiments, “machine-learned functional information” refers to actual learned information, while “machine-learnable functional information” relates to the theoretically learnable information capacity.

In some embodiments, for a conventional or traditional trained neural network, machine-learned functional information may correspond to information represented by trained weights, learned coefficients, trained lookup-table contents, trained operator selections, trained probabilities, trained state-transition choices, or other learned functional structure of the trained model. Moreover, machine-learned functional information may include learned parameterization information, learned parameterization bits, and information associated with latent parameterization circuitry for use in non-reconfigurable physical implementations of trained models. Accordingly, as used herein, “machine-learned functional information” refers generally to learned information that defines or characterizes the learned inference function of a trained model, whether the trained model is represented as a conventional neural network, a differentiable logic gate network, a fixed logic-gate network, a lookup-table network, or another trained computational network. In this sense, the term “machine-learned functional information” is intended to harmonize the terminology of the incorporated disclosures, without requiring a distinction among trained parameters, learned operator selections, learned node functions, learned truth-table contents, learned parameterization bits, and learned circuit topology information, provided that such information contributes to the learned function realized by the model.

To provide an illustration of “machine-learned functional information” compared to “machine-learnable functional information” in the context of conventional artificial neural networks, a neural network with 1 million parameters in floating-point 32-bit precision may have 32 million bits of machine-learnable functional information. A skilled person in the art may, in many cases, be able to reduce the precision to a 16-bit floating-point precision without significantly affecting the quality of the model, thereby establishing that, for the respective model instance, the “machine-learned functional information” may be less than or equal to 16 million bits. Moreover, depending on a variety of factors comprising training methods, architecture, data modality, data sets, quantization methods, and/or post-quantization techniques, a skilled person in the art may be able to quantize the model into an average number of bits per parameter (e.g., between 2 bits per parameter and 8 bits per parameter) just before starting to significantly degrading the quality of the model, thereby establishing that the machine-learned functional information of the model is approximately between 2 and 8 bits, respectively. The specific numbers are merely examples, and it is appreciated that different numbers or ranges may apply to specific implementations and embodiments.

The machine-learned functional information associated with a neural network model implemented using physical logic gates in an ASIC can be quantified and/or determined in various ways. By way of example and not limitation, a total machine-learned functional information count associated with an ASIC implementation of a neural network may be determined by reference to a known trained neural network model on which the ASIC was based (e.g., when such a model is available). As another non-limiting example, the total machine-learned functional information count associated with an ASIC implementation of a neural network may be determined with reference to a functionally equivalent trained neural network model. As another non-limiting example, the total machine-learned functional information count associated with an ASIC implementation of a neural network may be determined with reference to a functionally equivalent trained computational model. The latter two example approaches may be used to determine, or at least estimate a lower bound of, the machine-learned functional information when the original model is unavailable. In some embodiments, the functionally equivalent model may be selected as a practical model that a person of ordinary skill in the art, at a relevant time, would understand to be capable of providing equivalent or comparable inference functionality, such as equivalent or comparable task performance, output behavior, or benchmark performance. The total machine-learned functional information count for a given ASIC may thereby be determined from the amount of learned information required to specify that known or equivalent trained model.

In some embodiments, the total machine-learned functional information count is determined from one or more practical measures of model information content, including, by way of example and without limitation, a number of learned parameters, a size of a trained model representation, a quantized parameter representation, a lookup-table representation, a learned operator-selection representation, or another model representation commonly used by persons of ordinary skill in the art to characterize how much learned information is embodied by a trained model. In some embodiments, the determination may be based on a practical model representation that a person of ordinary skill in the art would consider reasonable at the relevant time.

In some embodiments, when the original trained neural network model used to create the ASIC is known, the machine-learned functional information associated with the ASIC may be determined directly from that known model. In other embodiments, when the original model is unavailable or proprietary, the machine-learned functional information associated with the ASIC may be estimated, bounded, or otherwise determined by comparing the functionality of the ASIC to a functionally equivalent trained neural network model (or comparable trained computational model), including, in some embodiments, a smallest practical model that a person of ordinary skill in the art could have made, at the relevant time, that contains the amount of learned functional information required to achieve equivalent or comparable inference functionality. In some embodiments, this equivalent-model approach yields an approximate value, a lower bound, an upper bound, or a range for the machine-learned functional information associated with the ASIC.

In various embodiments, the machine-learned functional information density of an ASIC sub-circuitry is determined as a function of: (i) a machine-learned functional information count associated with the known or functionally equivalent trained model or respective part of a model (including, but not limited to, expert model, block, or other fraction of a model represented by the respective sub-circuitry), divided by (ii) the number of physical logic gates in the ASIC sub-circuitry. Thus, a sub-circuitry may be characterized as embodying, on average, at least one-half bit, at least one bit, at least two bits, at least four bits, or at least ten bits of machine-learned functional information per physical logic gate. In some embodiments, the number of physical logic gates in the ASIC sub-circuitry is determined from the hardware implementation itself (e.g., from layout, netlist, gate-level representation, reverse engineering, or another physical or structural description of the ASIC), while the machine-learned functional information count is determined from the known or equivalent trained model as described above.

In some embodiments, an absence or reduced portion of gates that embody predefined arithmetic operations enables a high density of machine-learned functional information. For example, a circuitry that may learn up to 4 bits of functional information per learnable gate, and may post-synthesis retain a third of the number of learnable gates as physical gates, may have an upper bound of 12 bits of machine-learnable functional information per physical gate, and practically between half a bit and 10 bits of machine-learned functional information per physical gate.

In contrast, a binary neural network that learns up to one bit per weight may have an average of at least 5 gates within arithmetic adders per bit weight, and accordingly has an upper bound of around 0.2 bits of machine-learnable functional information per physical gate, and practically may have, in various embodiments, between 0.01 and 0.19 bits of machine-learned functional information per physical gate.

For additional illustration, an 8-bit per weight neural network may have on the order of 150-1000 physical gates within multiply-accumulator circuitry, which may depend on a range of characteristics, including data type, which may result in a range of corresponding upper bounds for the machine-learnable functional information per physical gate between 0.008 and 0.053 bits per physical gate. Practically, such a network may typically have, in various embodiments, between 0.001 and 0.05 bits of machine-learned functional information per physical gate.

In some embodiments, an application-specific integrated circuit includes sub-circuitry having a machine-learned functional information density greater than 0.5 bits per physical logic gate. In some embodiments, such density levels are achievable using the residual-initialization techniques and algorithms described herein. For example, residual initialization techniques may be utilized that enable deep node networks to be trained and then discretized into fixed logic while maintaining a comparatively high learned-function density relative to the number of physical logic gates. In some embodiments, sub-circuitries having substantially lower machine-learned functional information density (for example, densities corresponding to multiple physical logic gates per bit of machine-learned functional information) are indicative of implementations that are less information-dense and may correspond to conventional hard-encoding approaches that do not achieve the densities enabled by the presently described techniques.

In some embodiments, only a subset of the machine-learned functional information physically embodied in a sub-circuitry is affectively used during a particular inference cycle or evaluation interval. As used herein, machine-learned functional information is “affectively used” during a single cycle when the learned structural choice embodied by the hardware participates in a signal path and affects the output of a given physical logic gate for a given input during that cycle. To illustrate a disambiguation of “affectively used” learned information, information may only be “affectively used” when it is information that affects at least one signal path, which may be input-dependent. For example, when there is one bit of learned information in whether a 2-input physical gate is either a logical XOR or a logical OR, then that information is only affectively used in a cycle when both inputs are TRUE (TRUE XOR TRUE=FALSE, TRUE OR TRUE=TRUE), but if instead one input is TRUE and the other input is FALSE or both inputs are FALSE, then the respective information is not affectively used because the output of the respective physical gate is unaffected by whether the gate is an XOR or an OR. Even when the information is not affectively used, it may still be utilized (e.g., when the gate represented lies on an active inference path).

In various embodiments, the affective use of machine-learned functional information is input-dependent rather than parameterization time-multiplexed. That is, the learned logic selections and connections influence the output based on the input values propagating through the circuitry. In contrast, memory-based approaches may reuse the same parameterized resource in different scheduled time slots. Accordingly, the presently described device is input-dependent and does not require time-multiplexed memory reads. In various embodiments, an average of at least 0.125 bits per physical logic gate, at least 0.25 bits per physical logic gate, or another threshold amount of machine-learned functional information is affectively used during an active single cycle of the sub-circuitry to form the output based on the input.

As used herein, a “switching event” includes a logic-state transition of an output of a physical logic gate from one Boolean state to another Boolean state. In embodiments having pipelining, latches, flip-flops, or other sequential elements, the relevant cycle or interval may comprise one or more clock cycles used to produce the corresponding output, and the stated averages may be determined for a single inference, for a plurality of inferences, and/or over a representative workload. In various embodiments, when regions or pipeline stages are inactive (e.g., through gating) or regions or pipeline stages do not actively contribute to an inference in a given cycle, they may not be considered in that cycle for procuring a respective average.

In some embodiments, when normalized by switching activity, the sub-circuitry utilizes, on average, at least 1 bit or at least 2 bits of machine-learned functional information per switching event of the physical logic gates in transforming the input to the output. This input-dependent utilization metric pertains to the use of the retained, physically embodied subset of learned information during inference and does not imply reversibility to the totality of training-time learned information. To illustrate with an example, a multiply-accumulate circuitry having 500 physical gates and 8 bits of weight information (per cycle), may have on average (per cycle) 160 gate switches, and thereby may, on average, utilize up to 8 bits of learned information per 160 gate switches, thereby upper bounding the machine-learned functional information per gate switch to 8/160=0.05 bits, which may be 20× less learned information per gate switching event compared to at least 1 bit of machine-learned functional information per switching event.

In some embodiments, the physically implemented sub-circuitry is characterized by an aperiodic pattern of logic gate arrangements rather than by a periodic pattern of functional blocks. For example, at least 50% of the physical logic gates of the sub-circuitry may be arranged in an aperiodic pattern arising from learned gate selections and learned connections (e.g., wires, traces, omitted wires, position placement, interconnections, etc.), rather than in a repeated array of identical arithmetic or memory-access blocks. In some embodiments, the sub-circuitry implements a majority of the operations of a neural network, such that most operations along the inference data path are carried out by the non-reconfigurably physically implemented logic rather than by memory-backed or reconfigurable circuitry. In some embodiments, no more than 5% of the sub-circuitry comprises adder circuitry, because the learned function is implemented predominantly using logic selections and connections rather than arithmetic accumulation. These structural properties illustrate how retained machine-learned functional information may manifest in deployed circuitry and do not require that the deployed circuitry explicitly encode or preserve all information generated during training or optimization.

In various implementations, the logic circuitry may additionally include one or more flip-flops and/or latches. These elements may be useful for, by way of example, pipelining, state retention, sequential operation, and/or time-multiplexed evaluations. Nevertheless, in various embodiments, the learned function of the neural network or part thereof is still physically embodied by the non-reconfigurable physically implemented logic gates arranged in layers (e.g., at least 7 layers), such that the ASIC implements a learned inference function in fixed logic rather than by storing and repeatedly reading learned weights from a memory during inference. In embodiments including flip-flops, latches, or other sequential elements, the presence of such elements does not change the foregoing machine-learned functional information density framework, because the density is determined by dividing the learned functionality associated with a known or equivalent trained model by the number of physical logic gates in the relevant ASIC sub-circuitry. In some embodiments, the sub-circuitry comprises flip-flops or latches (e.g., for pipelining or recurrence).

As used herein, a “first set of nodes” may refer to nodes of a node network that are parameterized by differentiable parameters associated with respective predefined sets of potential logic gate operators, such that outputs of the nodes are computed using a first relaxation during training. A “second set of nodes” may refer to nodes of the node network that correspond to respective predefined logic gate operators, such that outputs of the nodes are computed using a second relaxation during training. In some embodiments, the second set of nodes is used to impose “structural inductive bias,” which generally refers to introducing fixed or predefined structural elements into a node network to encourage a desired architectural behavior, connectivity pattern, or signal-flow constraint. In some embodiments, a plurality of such predefined nodes is used repeatedly at multiple locations in a network, and such nodes may be referred to as “repeating structural inductive bias gates.” In some embodiments, the repeating structural inductive bias gates are arranged at multiple locations in a fixed logic gate network implemented in hardware, including, for example, at multiple pooling locations in a convolutional logic gate network, at multiple temporal-connection locations in a sequential logic gate network, and/or at multiple residual-activation-combination locations.

In some embodiments, the first relaxation is a probabilistic relaxation in which the differentiable parameters define probabilities corresponding to respective logic gate operators of a predefined set of potential logic gate operators (e.g., a finite set), and node inputs are represented as input activation probabilities between 0 and 1. In some embodiments, under the first relaxation, the node output is computed as an expectation under the assumption of independent node input probabilities. In some embodiments, the first relaxation comprises a continuous non-linear function of node inputs and differentiable parameters, and/or a stochastic sampling-based relaxation in which one or more candidate logic gate operators are sampled according to values derived from the differentiable parameters during training. In some embodiments, the first relaxation is based on a Yager t-norm and Yager t-conorm. In some embodiments, the second relaxation is a continuous relaxation and comprises at least one of (i) for a predefined node corresponding to a logical AND operator, a minimum operation as a relaxation of the logical AND operator, and (ii) for a predefined node corresponding to a logical OR operator, a maximum operation as a relaxation of the logical OR operator. In some embodiments, the second relaxation is based on a Hamacher t-norm and Hamacher t-conorm. In some embodiments, different relaxations are assigned to different subsets of nodes within the same node network.

As used herein, a “logic gate tree” refers to an acyclic, directed topology of interconnected logic gate nodes having a leaf-to-root information flow, in which a plurality of leaf inputs receive leaf input activations selected from one or more sources (e.g., network inputs and/or intermediate activations) and internal nodes compute node outputs that are provided to parent nodes, culminating in a root node output that defines a tree output activation. A “tree topology” is not limited to a balanced binary tree and may be balanced or unbalanced, and/or may be constructed subject to one or more connectivity constraints.

As used herein, “tree depth” may refer to a number of internal node levels between the leaf inputs and the root node. In one non-limiting example, a complete binary tree of depth d receives 2\hat{ }d leaf inputs and includes 2\hat{ }d−1 internal nodes. More generally, a k-ary tree may include internal nodes configured to receive k inputs (where k is an integer≥2). A “tree layer” (or level) refers to nodes of a logic gate tree that are at a common or approximately common depth/level in the tree, such that outputs of nodes of a lower tree layer are used as inputs to nodes of a higher tree layer.

In addition to operator-selection parameterizations that select among enumerated candidate functions (e.g., via a softmax), in some embodiments, a node having k discrete inputs is parameterized with an operator-selection parameterization in a truth-table form using a parameter vector having 2\hat{ }k entries, where each entry corresponds to a respective input pattern of the k inputs and is mapped into a range such as [0,1] (e.g., by a sigmoid mapping). In such embodiments, discretizing includes selecting, for each truth-table entry, a discrete output value (e.g., 0 or 1), thereby defining a discrete node operation (a truth table) without requiring selection from an enumerated list of candidate operations. In some other embodiments, values [−1,+1] are respectively used via respective transformations of the space.

As used herein, a “teacher model” broadly refers to any model that can provide supervision signals for training another model, including but not limited to a conventionally trained artificial neural network, a reinforcement-learning policy/value model, an ensemble of models, a heuristic model, a probabilistic model, a decision-tree model, and/or a previously trained logic gate network. A “student model” broadly refers to any model trained with teacher-model supervision, including a differentiable logic gate network and/or a fixed logic gate network derived therefrom. “Teacher output values” (also referred to as teacher predictions or supervision signals) may include hard labels, soft labels, logits, probabilities, normalized or unnormalized scores, action distributions, intermediate representations, embeddings, and/or per-node or per-layer targets. In some embodiments, teacher supervision is applied at an output-representation level adapted for logic gate networks, such as class scores obtained by aggregating multiple output bits/gates per class, action scores, and/or other structured outputs. A “training data set” or “training corpus” includes any collection of inputs and corresponding target values, including (i) direct ground-truth labels, (ii) teacher-labeled data generated by evaluating the teacher model on inputs, (iii) synthetic inputs, (iv) simulated environment observations, and/or (v) mixtures thereof. Further, “training” includes minimizing any objective that encourages a student output to match a teacher output, including divergence-based losses (e.g., Kullback-Leibler divergence), cross-entropy losses, mean-squared error losses, margin-based losses, and/or composite losses that combine task loss and distillation loss; and “temperature scaling” includes any scaling applied to logits, scores, and/or probabilities to adjust entropy or smoothness of the supervision signal.

The systems and methods described herein may be implemented in a wide variety of computing environments and are not limited to any particular hardware, software, or network architecture. A “computing system” may include one or more processors (e.g., CPUs, GPUs, microcontrollers, DSPs), accelerators (e.g., NPUs, TPUs), and/or programmable or custom logic (e.g., FPGAs, ASICs), and may further include one or more memories, buses, interconnects, storage devices, and communication interfaces. Any “module,” “engine,” “unit,” “component,” or “block” described herein may be implemented in hardware, software, firmware, or any combination thereof, and may be integrated into a single device or distributed across multiple devices (e.g., across a client device and one or more servers). For example, training operations may be executed in a cloud computing environment, and inference operations may be executed on an edge device, embedded controller, FPGA, and/or ASIC. Further, “memory” and “computer-readable medium” include one or more non-transitory storage media (e.g., RAM, ROM, flash, SSD, HDD, optical media) that store instructions and/or data, including trained parameters, operator selections, connection-index arrays, circuit descriptions, and/or other representations of trained or fixed networks.

The figures and the corresponding detailed description are intended to be illustrative and non-limiting. Functional blocks shown in the figures may represent hardware components, software components, data structures, and/or combinations thereof, and boundaries between blocks are exemplary and may be rearranged, subdivided, combined, or omitted in various implementations. Any flowcharts, sequences, or steps described herein (including training iterations and forward/backward passes) are examples and may be performed in different orders, repeated, performed concurrently, and/or performed with additional or fewer steps, unless expressly stated otherwise. As used herein, the terms “comprising,” “including,” and “having” are open-ended and do not exclude additional elements; “or” is inclusive unless the context clearly indicates otherwise; “based on” means “based at least in part on;” and terms such as “first,” “second,” and the like are used merely as labels and do not imply a required order or ranking. Ranges and numerical examples are illustrative, and terms such as “about” and “approximately” encompass variations consistent with the disclosed purpose and the tolerances of a given implementation.

Many existing computing systems, methods, and devices may be used in combination with the systems and methods described herein. Some of the infrastructure that can be used with embodiments disclosed herein is already available, such as general-purpose computers, computer programming tools and techniques, digital storage media, and communication links. A computing device or controller may include a processor, such as a microprocessor, a microcontroller, or logic circuitry. Various technologies, systems, architectures, and applications are relevant to the presently described embodiments. Examples of such technologies, systems, architectures, and applications include, but are not limited to, certain aspects of deep neural networks, image recognition, recommender systems, medical diagnosis, language processing, machine learning inference tasks, character recognition, voice detection, multi-modal machine learning models, generative AI, image processing, encoding, decoding, encryption, and the like.

A processor and other processing components may include and/or utilize a special-purpose processing device, such as application-specific integrated circuits (ASIC), programmable array logic (PAL), programmable logic array (PLA), programmable logic device (PLD), field programmable gate array (FPGA), or other customizable and/or programmable device. A computing device may include a machine-readable storage device, such as non-volatile memory, static RAM, dynamic RAM, ROM, CD-ROM, disk, tape, magnetic media, optical media, flash memory, or other machine-readable storage medium. Various aspects of certain embodiments may be implemented using hardware, software, firmware, or a combination thereof.

The components of the disclosed embodiments, as generally described and illustrated in the figures herein, could be arranged and designed in a wide variety of different configurations. Furthermore, the features, structures, and operations associated with one embodiment may be applicable to or combined with the features, structures, or operations described in conjunction with another embodiment. In many instances, well-known structures, materials, or operations are not shown or described in detail to avoid obscuring aspects of this disclosure.

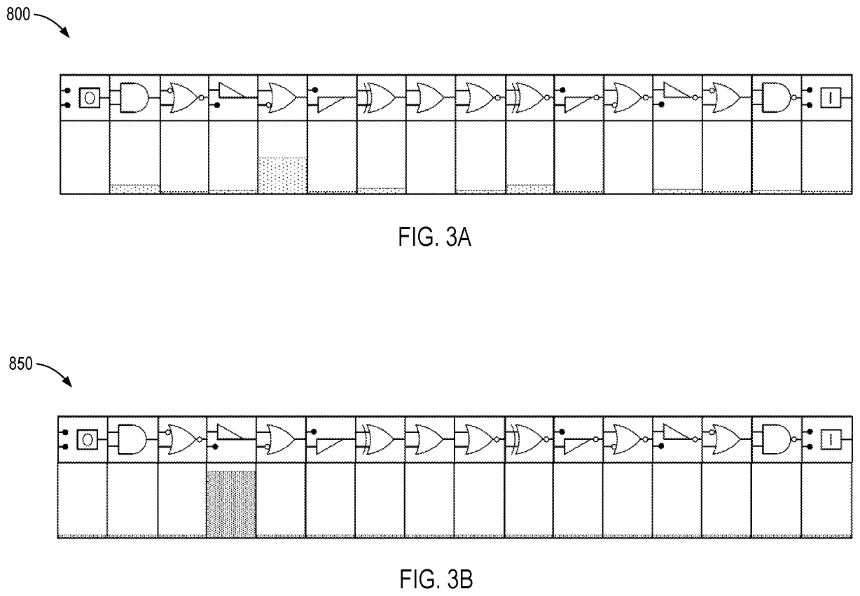

FIGS. 3A and 3B illustrate example operator-selection probability distributions 800 and 850, respectively, for a node of a differentiable logic gate network at initialization, comparing (i) a conventional random initialization and (ii) a “residual initialization” that biases the node toward a feedforward (wire-like) behavior. FIGS. 3A and 3B are illustrated as rows of candidate logic gate operators (shown as logic gate symbols), each corresponding to a respective entry in a predefined set of logic gate operators for the node. In the illustrated example, the predefined set includes a plurality of two-input logic operators, including constant operators (e.g., constant 0 and constant 1), Boolean-combination operators (e.g., AND, OR, XOR, NAND, NOR, etc.), and feedforward logic gate operators (e.g., direct-connection and inverter forms).

In some embodiments, each node in the differentiable logic gate network is parameterized by a set of differentiable parameters corresponding to the predefined set of logic gate operators for that node. For example, the node may be parameterized by a vector of real-valued scores (sometimes referred to as “logits” or “unnormalized scores”), where each score corresponds to a respective candidate logic gate operator. The differentiable parameters may be mapped to an operator-selection probability distribution over the predefined set of logic gate operators using a softmax operation, thereby producing a categorical probability distribution with non-negative entries that sum to 1. Various embodiments include alternative functions mapping from differentiable parameters to per-operator probabilities, including but not limited to computations wherein the probabilities are not computed, and instead utilize a simplified computation that implicitly uses the probabilities but that does not explicitly compute the probabilities (e.g., when the operator probability is an intermediate stage between two previously known computations that may be unified). During differentiable training, the node output may be computed as a differentiable combination (e.g., a weighted sum) of the outputs of the candidate logic gate operators, with weights determined by the operator-selection probability distribution.

In some embodiments, each candidate logic gate operator is evaluated using a differentiable (real-valued) relaxation of a corresponding Boolean truth-table behavior. For example, rather than operating exclusively on hard binary activations, the differentiable logic gate network may propagate activations in a continuous range (e.g., in [0, 1]) and compute, for each candidate logic gate operator, a relaxed operator output based on the node inputs. The node output may then be computed as the expected value (or another differentiable aggregation) of the candidate operator outputs under the operator-selection probability distribution defined by the node's differentiable parameters.

FIG. 3A illustrates an example initialization 800 in which the differentiable parameters (e.g., the logits corresponding to candidate logic gate operators) are initialized as random draws from a distribution (e.g., a Gaussian distribution). In such an initialization, applying softmax to the randomly initialized parameters can yield a comparatively “washed out” operator-selection probability distribution, with probability mass spread across many candidate logic gate operators, with no single operator strongly preferred. In FIG. 3A, this is visually represented by multiple candidate logic gate operators having non-trivial assigned probability (shown by non-zero bar heights beneath multiple gate symbols).

In some embodiments, washed-out operator-selection probability distributions can cause node outputs (and, in deeper networks, layer activations) to become “washed out” as well. For example, expected activations may quickly converge toward intermediate values (e.g., toward approximately 0.5) as depth increases, thereby degrading information flow through the network at initialization. In addition, such washed-out activations can contribute to vanishing gradients in deeper differentiable logic gate networks. For example, with Gaussian initialization, the gradient norm may decay by a substantial factor (e.g., by approximately 0.1-0.2) at each logic gate during backpropagation through an initialized network, which can exponentially slow training as network depth increases.

In conventional neural networks (e.g., convolutional neural networks), residual connections are commonly used to mitigate vanishing gradients and information loss in deep architectures by adding the block's input to its output. However, in pure logic gate-based computation, direct additive residual connections are generally not available and/or may be undesirable, because addition is not a native Boolean operation, and implementing addition may require additional circuitry and/or additional nodes dedicated to performing such additions.

FIG. 3B illustrates an example “residual initialization” 850 for a node of a differentiable logic gate network. In residual initialization, the differentiable parameters of the node are initialized such that the initial operator-selection probability distribution assigns the greatest (or highest) probability to a feedforward logic gate operator, relative to probabilities assigned to other candidate logic gate operators in the predefined set. In FIG. 3B, this is visually represented by a dominant probability mass concentrated on a single candidate operator (shown by a much larger bar height beneath a feedforward-type gate symbol), with little to no probability mass assigned to other operators at initialization.

As used herein, a “feedforward logic gate operator” includes an operator that provides direct-connection behavior (wire-like behavior) and/or inversion behavior for a node input, without performing a Boolean combination of two inputs. For example, in various embodiments, the feedforward logic gate operator comprises one of: (i) a direct-connection operator configured to output a first node input (wire-first-input), (ii) a direct-connection operator configured to output a second node input (wire-second-input), (iii) an inverter operator configured to output an inverse of the first node input (inverter-first-input), or (iv) an inverter operator configured to output an inverse of the second node input (inverter-second-input). In some embodiments, selecting “A” (the first input) as a canonical feedforward choice is functionally interchangeable with selecting “B” (the second input), and is often also interchangeable (e.g., by symmetry) with selecting inverters “1-A” or “1-B.”

As used herein, “learning a differentiable logic gate” (and, more generally, learning a trainable multi-input node that is discretizable to a discrete operation) encompasses learning and/or identifying a discrete node function that may be represented as lookup-table (“LUT”) contents (i.e., a truth table). For a node having k discrete (e.g., binary) inputs, a discretized form of the node may be fully specified by a LUT having 2\hat{ }k entries, with each LUT entry defining an output value for a respective input pattern of the k inputs. In some embodiments, the LUT contents are represented as a vector T∈{0,1}\hat{ }{2\hat{ }k}, where T[i] denotes the output associated with input-pattern index i. In one non-limiting indexing convention for binary inputs x₀, x₁, . . . , x_{{k-1}}∈{0,1} with a corresponding index and discretized node output, the number of distinct Boolean functions of k binary inputs is 2\hat{ }{2\hat{ }k}.

Accordingly, learning a k-input gate/node may be viewed equivalently as: (i) learning the 2\hat{ }k LUT entries (the truth-table contents) that define the node's discrete mapping, and/or (ii) selecting one LUT-contents vector from among 2\hat{ }{2\hat{ }k}possible LUT contents vectors (i.e., selecting one of 2\hat{ }{2\hat{ }k} candidate discrete node functions). Thus, in embodiments where a node is trained in a “trainable form” (e.g., by maintaining real-valued parameters that are later discretized), “learning a differentiable logic gate” includes learning parameters that, upon discretization, determine the node's LUT contents, regardless of whether the trainable form is implemented as (a) a selection mechanism over a library of candidate discrete functions (e.g., a probability distribution over candidate truth tables), or (b) a direct parameterization of the truth table itself (e.g., real-valued parameters corresponding to respective truth-table entries that are discretized entry-wise).

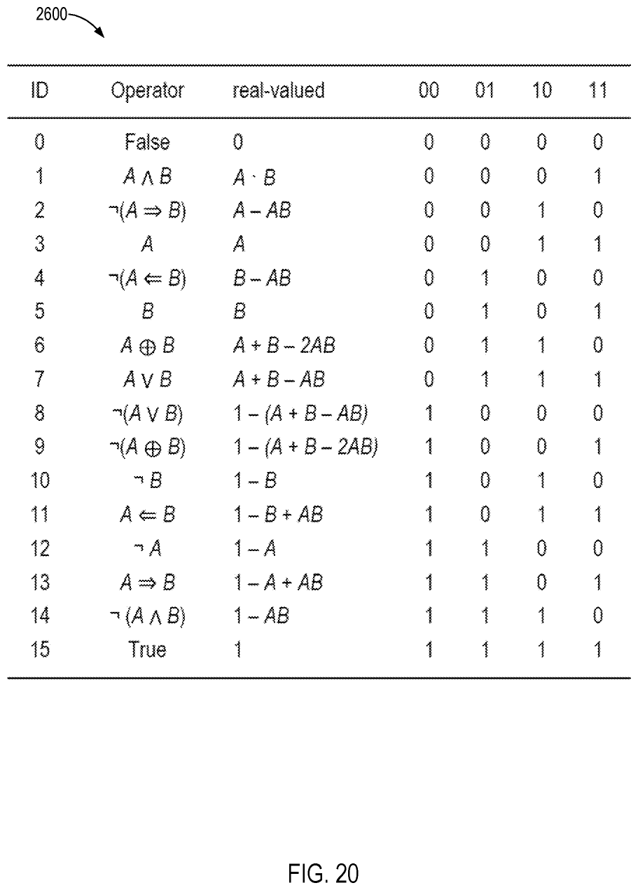

By way of a non-limiting example, for k=4, the node has 2\hat{ }4=16 possible input patterns and can therefore be specified by a 16-bit LUT contents vector T∈{0,1}\hat{ }{16}. The total number of possible discrete node functions in this case is 2\hat{ }{2\hat{ }4}=2\hat{ }{16}=65,536, corresponding to all possible 16-bit LUT-contents vectors. Thus, learning a four-input differentiable logic gate (or other trainable four-input discretizable node) may correspond to learning and/or identifying the 16 LUT entries that define the node's discretized operation, or equivalently selecting one 16-bit LUT-contents vector from among 65,536 possible LUT-contents vectors. In the special case k=2, the LUT has 2\hat{ }2=4 entries, and there are 2\hat{ }{2\hat{ }2}=16 possible discrete functions, corresponding to the sixteen two-input Boolean functions (e.g., as described herein, including in conjunction with FIG. 20 below).

In some embodiments, a single implemented logic element simultaneously embodies multiple learned design choices. For example, a single implemented logic element may simultaneously embody a selected node function together with one or more selected predecessor-input connections. For instance, a one-of-16 two-input function selection together with two one-of-8 (distinct) input-source selections may embody an illustrative total of up to approximately 9 to 10 bits of machine-learnable functional information for one two-input physical logic element. This calculation is based on (i) the physical logic element having two inputs, (ii) 10 possible choices (3.322 bits), and (iii) 3 bits for each of the one-of-8 choices. It is appreciated that other embodiments, configurations, and implementations may embody greater or lesser amounts.

In some embodiments, residual initialization is implemented by initializing a parameter (or logit) corresponding to a selected feedforward operator to be larger than those of other parameters, so that an operator-selection mapping (e.g., a softmax) assigns a substantially higher selection probability to the selected feedforward operator than to any other candidate operator. For example, in one non-limiting implementation, the probability for a wire operator (e.g., “A”) is initialized to approximately 90% while other candidate operators share the remaining probability mass (e.g., about 0.67% each when sixteen candidate operators are used). More generally, in embodiments that use 2\hat{ }{2\hat{ }k}parameters prior to a softmax to select among 2\hat{ }{2\hat{ }k}candidate Boolean functions of k inputs, the residual initialization scheme may be implemented by setting all parameters to 0, except the parameter which corresponds to the gate choice “wire A” (or equivalently “wire B” etc.), which may be set to a value larger than 0, e.g., to 5. Alternatively, the values may be perturbed with random noise, and, optionally, only a subset of trainable nodes (or differentiable gates) may be initialized using residual initialization.

However, when using 2\hat{ }k parameters, which are each mapped into the [0,1] range (e.g., a truth-table parameterization in which a k-input node is represented by 2\hat{ }k trainable values corresponding to respective input patterns), the foregoing softmax-based residual initialization scheme does not apply. Instead, residual initialization may be implemented using a parameter vector that leads, upon discretization, to “wire A” (or equivalently “wire B”, etc.). For example, in the case of k=2 and 2\hat{ }k=4, the system may use [−σ, −σ, σ, σ]\hat{ }T for some σ>0 to implement “wire A”. Equivalently, to implement “wire B” the system may use [−σ, σ, −σ, σ]\hat{ }T for some σ>0.

Generally, for arbitrary k, the system may initialize the vector to [(1 if x//e % 2 else −1)·σ for i in range(2k)]\hat{ }T** (where, in this expression, x corresponds to the index i) for some a>0, where e is a power of two specifying the initial wire choice. Inverters can be obtained during initialization analogously. Again, the initialization may be randomly perturbed, and, optionally, only a subset of trainable nodes (or differentiable gates) may be initialized using residual initialization. The residual initialization scheme typically accelerates training (in terms of the number of steps), improves stability, and yields better models. As another example, for arbitrary k, in embodiments that parameterize a k-input node in a truth-table form using a 2\hat{ }k-entry parameter vector (one parameter per input pattern), residual initialization to implement a pass-through of a selected input x_r (for some r∈{0, . . . , k−1}) may be performed by initializing the truth-table parameters according to the r-th bit of the input-pattern index. For example, using an index convention i=x0+2·x1+ . . . +2\hat{ }{k−1}·x{k−1}, the system may initialize a parameter vector v∈R\hat{ }{2\hat{ }k} as v[i]=+σ when ((i>>r) & 1)=1 and v[i]=−σ when ((i>>r) & 1)=0, for a selected σ>0, such that discretizing v entry-wise yields a truth table corresponding to “wire x_r.” Residual initialization to implement an inverter of x_r may be performed by negating the foregoing initialization (or equivalently, swapping the +a and -a assignments). In some embodiments, the system perturbs the initialized values with random noise and/or applies the residual initialization to only a subset of trainable nodes.

Residual initialization can provide a residual-connection behavior in a differentiable logic gate network without hard-wiring a residual connection or adding additional logic gate nodes dedicated to implementing residual connections. In practice, initializing nodes to be primarily feedforward (wire-like) at the beginning of training can preserve information flow through deeper layers of the network and reduce gradient decay. As training progresses, nodes that benefit from performing non-feedforward logic operations may learn to shift probability mass away from the initial feedforward operator toward other candidate logic operators (e.g., AND, OR, XOR). Thus, residual initialization may serve as a differentiable analogue of residual connections while remaining compatible with logic gate-based computation and subsequent discretization into a fixed-logic gate network.

In some embodiments, structural inductive bias is additionally or alternatively imposed using a predefined gate configured to combine an activation from one layer of a node network with a residual activation from a different layer of the node network. In some embodiments, the predefined gate is included in the second set of nodes and uses the second relaxation rather than the first relaxation used for learnable nodes. In some embodiments, the predefined gate is repeated multiple times within the node network to provide multiple structural inductive-bias gates for a residual-activation combination. In some embodiments, the combination of activation and residual activation is performed without requiring the combination gate itself to be learned via differentiable operator selection.

In some embodiments, residual initialization enables efficient and effective training of deeper differentiable logic gate networks (e.g., beyond six layers) by addressing both the loss of information in washed-out activations and the vanishing-gradient behavior in washed-out operator-selection distributions at initialization. In some embodiments, the “strength” of residual initialization (i.e., the degree to which the probability distribution is biased toward the feedforward operator) is controlled by a hyperparameter corresponding to the relative magnitude of the feedforward operator's initial logit compared to other logits. For example, in one non-limiting implementation, a hyperparameter (e.g., z3) controls the strength of residual initialization. In some experiments, performance is observed to be satisfactory when such a hyperparameter is at or above a threshold (e.g., z3≥2), and in deeper or larger models, larger values (e.g., about 5) may be favorable (for example, because smaller values may be insufficient to support training in deeper architectures).

In various embodiments, the residual initialization techniques described herein are applicable to node networks having a wide range of depths, including relatively shallow networks and very deep networks. By way of non-limiting example, residual initialization may be used in networks having more than 6 layers, more than 10 layers, more than 20 layers, about 50 layers, about 100 layers, about 250 layers, and in some embodiments, more than 1000 layers. In some embodiments, the residual initialization is selected such that a sufficient number of nodes initially provide residual signal paths through the network, thereby preserving information flow and enabling optimization across large depths that would otherwise be difficult, impractical, or impossible to train with conventional random initialization.

In some embodiments, the strength of the residual initialization is selected at least in part based on the target depth of the network. For example, as the number of layers increases, the system may increase the degree to which the trainable nodes are biased toward residual operations at initialization. For example, the degree of bias may be increased by increasing the logit magnitude, increasing the coefficient bias, increasing the truth-table sign-pattern magnitude, increasing the fraction of nodes initialized as residual, or otherwise increasing the initial dominance of residual behavior. As such, stronger residual initialization may be used to facilitate training of networks having about 50 layers, about 100 layers, about 250 layers, or, in some embodiments, in excess of 1000 layers. Correspondingly, after training and discretization, hardware implementations such as ASICs may embody node networks having a wide range of layer counts, including, by way of example and without limitation, about 7 layers, about 15 layers, about 23 layers, about 50 layers, about 100 layers, about 250 layers, and more than 1000 layers between at least one input and at least one output, depending on the architecture and synthesis result.

In some embodiments, residual initialization also biases trained models to use feedforward gate choices in portions of the network where feedforward behavior is sufficient, which can be advantageous for hardware implementations. For example, feedforward gates may be implemented as wires (or wire-like interconnects), thereby potentially reducing transistor count and chip area in a synthesized hardware realization (e.g., FPGA or ASIC), particularly after logic synthesis and simplification to eliminate trivial feedforward nodes or otherwise simplify the learned circuit structure.

As used herein, a multi-input node (e.g., a two-input node) is “residualizable” when its trainable form supports discretization to either: (i) a multi-input operation that functionally depends on at least two of the node inputs (or at least two non-constant node inputs), or (ii) a residual operation that functionally depends on only a single one of the node inputs, such as an identity/pass-through of a selected input or an inverter of a selected input. A node is referred to as a “residual node” when, in a discretized form of the node network (e.g., after applying a discretization rule that selects a fixed per-node operation), the node implements a residual operation. In various embodiments, residual initialization comprises selecting residual operations for a plurality of residualizable nodes (e.g., for more than half of the residualizable nodes in one or more layers, and in non-limiting examples for about 70%, about 90%, or substantially all such nodes), thereby providing residual signal paths through the untrained network while still permitting training to transition selected nodes to multi-input operations. In some embodiments, the trainable parameters that define the trainable forms are updated using a gradient-based optimization algorithm and/or a gradient-approximating optimization algorithm, such as by using exact gradients, surrogate gradients, straight-through estimators, stochastic perturbation methods, finite-difference estimates, and/or other comparable approaches.

As used herein, a discretized node function “functionally depends” on a particular input when varying that input (while holding other non-constant inputs fixed) can change the node output for at least one setting of the other inputs. In some embodiments, functional dependence is evaluated after applying logic-synthesis simplifications such as constant propagation. Constant propagation is a transformation in which known-constant values (e.g., inputs fixed to logical 0 or logical 1) are propagated through downstream logic to simplify node functions (for example, simplifying TRUE AND D to D, and simplifying TRUE XOR D to NOT D). In this context, a “non-constant” input refers to an input that is not provably constant after constant propagation and any associated simplification. Accordingly, a node may be characterized as residual when, after constant propagation, its output depends on only a single non-constant input (even if the node originally received two inputs and was configurable to a multi-input operation).

For example, consider a node network including nodes C and E, where node C has inputs A and B and node E has inputs C and D. In one embodiment, node C is residualizable and is discretized (or residually initialized) to a residual operation C=C(A,B)=A (or C=C(A,B)=NOT A), such that C depends on only one of its inputs. If, due to upstream simplification, C is thereafter determined to be constant (e.g., C=C(A,B)=TRUE), then a downstream node E may also be residual after constant propagation even when E is configured with a two-input operation. For example, if E is configured as E=E(C,D)=C AND D, constant propagation yields E=TRUE AND D=D; and if E is configured as E=E(C,D)=C XOR D, constant propagation yields E=TRUE XOR D=NOT D. Similarly, if X is a constant TRUE and a node output is Y=X XOR A, then constant propagation yields Y=NOT A, and Y is still characterized as residual because it functionally depends on only a single non-constant input A. In various embodiments, the constant nodes that, via constant propagation, induce a residual gate may be counted among the residual gates when determining the proportion of residual gates among a node network, since they, jointly with a respective downstream gate, create a residual function.

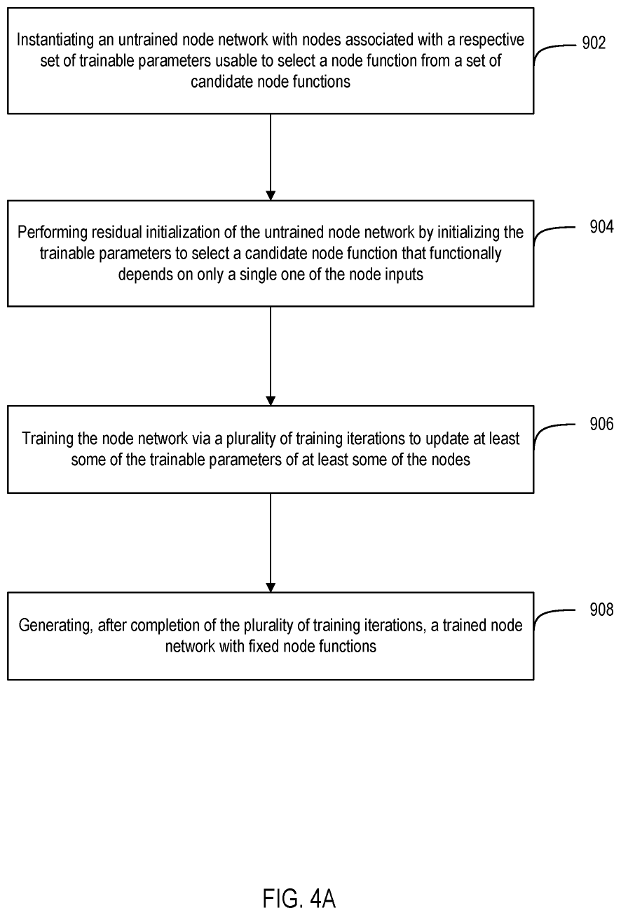

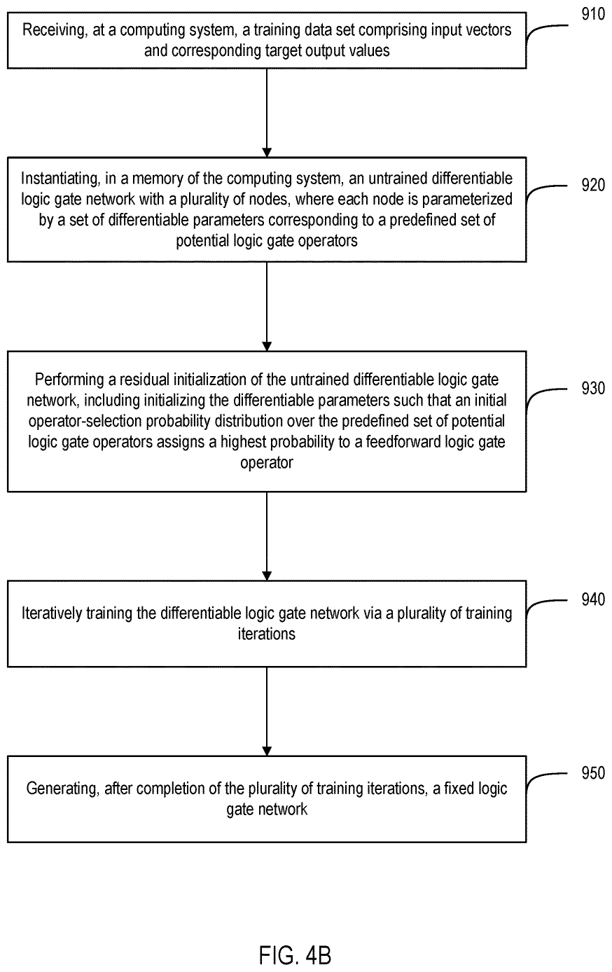

FIG. 4A illustrates an example process for performing residual initialization, according to one embodiment. In some embodiments, the operations of FIG. 4A are performed by a computing system comprising one or more processors and memory storing instructions that cause the computing system to perform the operations described herein. At step 902, the computing system instantiates an untrained node network with nodes associated with a respective set of trainable parameters. The trainable parameters are used to select a node function for at least some of the nodes from a set of candidate node functions, including, in some embodiments without limitation, candidate node functions that depend on at least two of the node inputs.

At step 904, the computing system performs a residual initialization of the untrained differentiable logic gate network by initializing or setting the trainable parameters to select a candidate node function that functionally depends on only a single one of the node inputs. In some embodiments, residual initialization includes initializing the differentiable parameters of at least a plurality of nodes such that an initial operator-selection probability distribution assigns a highest probability to a feedforward logic gate operator (i.e., a candidate node function that functionally depends on only a single one of the node inputs).

In step 906, the computing system iteratively trains the differentiable logic gate network via a plurality of training iterations. In some embodiments, each training iteration includes forward-propagating a batch of inputs through the differentiable logic gate network to generate a training output. During forward propagation, the computing system computes, for each node, a differentiable node output as a function of outputs of the potential logic gate operators of that node. In some embodiments, the computing system computes a loss value that quantifies the difference between the training output and the corresponding target output values, and updates the differentiable parameters using a training optimization algorithm (e.g., a gradient-based method such as Adam).

At step 908, after completing the plurality of training iterations, the computing system generates a trained node network with, for example, fixed node functions. In some embodiments, generating the fixed logic gate network includes discretizing the differentiable logic gate network by selecting, for each of at least some nodes, a single logic gate operator from the predefined set of potential logic gate operators based on the node's trained differentiable parameters. In some embodiments, the fixed logic gate network is representable as a circuit description (e.g., a netlist, a hardware-description-language representation, or other circuit data) and may be synthesized to hardware, including implementation in programmable logic (e.g., an FPGA) and/or fabrication as an application-specific integrated circuit (ASIC). In some embodiments, logic synthesis and optimization are applied to simplify the fixed logic gate network, including eliminating trivial feedforward nodes, constant-output nodes, and/or unconnected nodes, and further including implementing feedforward nodes as wires that omit transistor-based logic gates where applicable.

FIG. 4B is a flow diagram illustrating an example process for training a differentiable logic gate network using residual initialization and generating a fixed logic gate network after training. In some embodiments, the operations of FIG. 4B are performed by a computing system comprising one or more processors and memory storing instructions that cause the computing system to perform the operations described herein.

At step 910, the computing system receives a training data set comprising input vectors and corresponding target output values. The training dataset may correspond to an inference task such as classification, regression, reinforcement learning policy inference, or other machine learning inference tasks. In some embodiments, the training data set is stored in memory and accessed in batches for iterative training.

At step 920, the computing system instantiates, in memory, an untrained differentiable logic gate network having a plurality of nodes. In some embodiments, the nodes are arranged in a plurality of layers. Each node is parameterized by a respective set of differentiable parameters corresponding to a predefined set of potential logic gate operators for that node. In some embodiments, each node has exactly two inputs and produces a single output activation, although other node arities are possible. In some embodiments, each node is parameterized by a vector of real-valued scores, which are mapped via softmax to an operator-selection probability distribution over the predefined set of logic gate operators.

At step 930, the computing system performs a residual initialization of the untrained differentiable logic gate network. In some embodiments, residual initialization includes initializing the differentiable parameters of at least a plurality of nodes such that an initial operator-selection probability distribution assigns a highest probability to a feedforward logic gate operator. In some embodiments, substantially all nodes in one or more layers, blocks, or stages are initialized with residual. In some embodiments, a subset of nodes is residual-initialized, for example, nodes in deeper layers, nodes within a convolutional block, and/or nodes in an output head, to improve initial information flow and gradient propagation through portions of the network most susceptible to vanishing gradients.

In some embodiments of step 930, residual initialization is implemented by selecting, for a given node, a feedforward operator (e.g., wire-first-input, wire-second-input, inverter-first-input, or inverter-second-input) and initializing the node's differentiable parameters to bias the operator-selection probability distribution toward that selected feedforward operator. In some embodiments, the bias assigns approximately 0.85 to 0.95 probability to the selected feedforward operator, while distributing the remaining probability mass substantially uniformly across the remaining candidate operators. In one non-limiting example using sixteen candidate operators, the selected feedforward operator is assigned to have approximately 0.9 probability while each of the other candidate operators is assigned approximately 0.0067 probability.

In some embodiments, the residual initialization of step 930 is performed using any of the foregoing parameterizations. For example, in embodiments where a node selects among candidate functions using a softmax over 2\hat{ }{2\hat{ }k}parameters, the system may bias the corresponding feedforward (“wire”) parameter as described above, and in embodiments where a node is parameterized by a 2\hat{ }k-entry vector, the system may initialize the vector to a pattern that discretizes to a selected wire or inverter function (e.g., “wire A,” “wire B,” “NOT A,” or “NOT B”).”

At step 940, the computing system iteratively trains the differentiable logic gate network via a plurality of training iterations. In some embodiments, each training iteration includes forward-propagating a batch of inputs through the differentiable logic gate network to generate a training output. During forward propagation, the computing system computes, for each node, a differentiable node output as a function of outputs of the potential logic gate operators of that node, weighted according to the operator-selection probability distribution defined by the node's current differentiable parameters. In some embodiments, the computing system computes a loss value that quantifies the difference between the training output and the corresponding target output values, and updates the differentiable parameters using a training optimization algorithm (e.g., a gradient-based method such as Adam). As training proceeds, the computing system may update differentiable parameters such that, for at least some nodes, a non-feedforward logic gate operator becomes more probable than the feedforward logic gate operator originally emphasized by residual initialization, thereby enabling the network to learn non-trivial logic operations where beneficial.

At step 950, after completing the plurality of training iterations, the computing system generates a fixed-logic gate network. In some embodiments, generating the fixed logic gate network includes discretizing the differentiable logic gate network by selecting, for each of at least some nodes, a single logic gate operator from the predefined set of potential logic gate operators based on the node's trained differentiable parameters (e.g., selecting the operator having the highest probability in the operator-selection probability distribution). In some embodiments, the fixed logic gate network is representable as a circuit description (e.g., a netlist, a hardware-description-language representation, or other circuit data) and may be synthesized to hardware, including implementation in programmable logic (e.g., an FPGA) and/or fabrication as an application-specific integrated circuit (ASIC). In some embodiments, logic synthesis and optimization are applied to simplify the fixed logic gate network, including eliminating trivial feedforward nodes, constant-output nodes, and/or unconnected nodes, and further including implementing feedforward nodes as wires that omit transistor-based logic gates where applicable.

Although FIGS. 4A and 4B illustrates particular sequences of operations, it will be understood that, in various embodiments, the depicted operations may be performed in different orders, may be combined, and/or may be supplemented with additional operations. For example, residual initialization (step 930) may be applied selectively to particular layers or blocks, may use different feedforward operators for different nodes, and/or may be configured with different initialization strengths for different portions of the differentiable logic gate network to match desired training dynamics and deployment constraints.

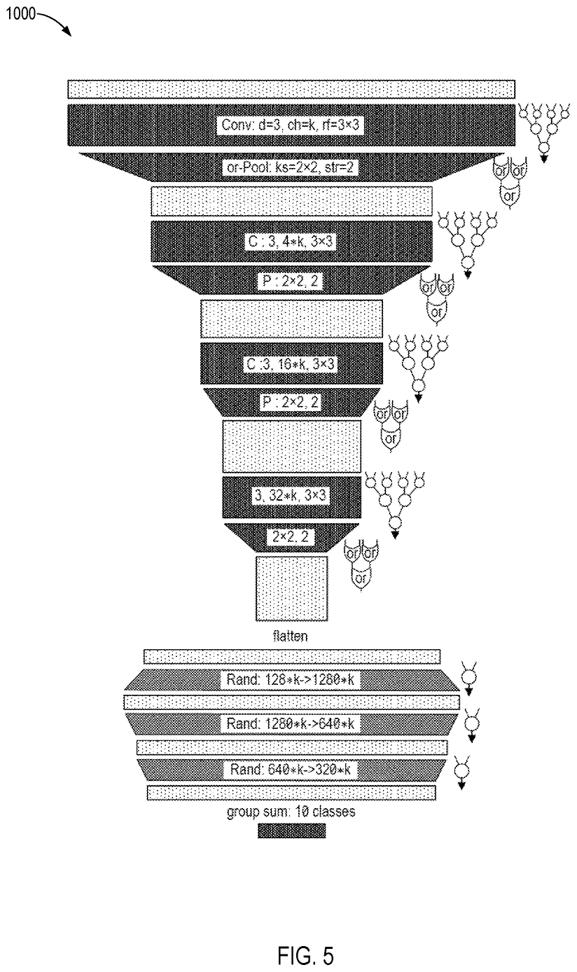

FIG. 5 illustrates an example convolutional logic gate network architecture 1000 (also referred to herein as a LogicTreeNet architecture) that is configured to perform an inference task (e.g., image classification) using logic gate-based computation. In various embodiments, the architecture 1000 includes a plurality of convolutional logic gate-tree blocks (“Conv” blocks) and corresponding pooling blocks, followed by a classification head comprising one or more randomly connected differentiable logic layers (“Rand” layers) and a GroupSum output stage. In some embodiments, the architecture 1000 follows a pattern similar to conventional convolutional architectures by applying convolutional blocks with pooling at the end of each block, where each block reduces spatial resolution (e.g., by a factor of 2×2) while increasing the number of channels, until a target spatial resolution (e.g., 2×2) is reached. Thereafter, the architecture 1000 applies a classification head and produces class scores (or other outputs) using a group aggregation operation.

In the illustrated example, the architecture 1000 is defined by a hyperparameter k that controls the network width (e.g., the number of kernels and/or channels across one or more stages). In some embodiments, k may be selected from a set of discrete model scales (e.g., S, M, B, L, G) that correspond to different width values, such that smaller k values yield smaller, faster models, and larger k values yield larger, more accurate models.

Each Conv block of FIG. 5 is configured to perform a convolution-like operation in which an input activation tensor is convolved with one or more learnable logic gate trees, thereby producing one or more output channels. In various embodiments, each convolution kernel is implemented as a logic gate tree (e.g., a complete binary tree) of depth d, where the internal nodes of the tree comprise logic gate operators and the leaves are selected from the receptive field of the input activation tensor. For example, in some embodiments, a kernel with depth d comprises (2\hat{ }d−1) internal logic gate nodes and receives 2\hat{ }d leaf inputs from the receptive field, so that the kernel computes a tree-structured composition of logic operations.

In some embodiments, leaf inputs to each logic gate tree are selected from a predefined receptive field of size and across one or more input channels. In some embodiments, the selection of leaf inputs is determined by one or more connection-index tensors that specify: (i) which input channel is selected for each leaf input and (ii) a spatial offset within the receptive field for each leaf input. In some embodiments, the connection indices are randomly initialized (e.g., pseudo-randomly) and may remain fixed during training while the logic gate operator choices in the tree are learned.

As illustrated, the Conv blocks may use a receptive field size of 3×3 (“rf=3×3”) and a tree depth of d=3 (e.g., “Conv: d=3, ch=k, rf=3×3” for the first block), although other receptive field sizes and tree depths may be used. In some embodiments, each output channel corresponds to a distinct tree kernel, and the set of tree kernels in a block defines the number of output channels for that block. In the illustrated example architecture 1000, the first Conv block uses k kernels (channels), the second uses 4k kernels, the third uses 16k kernels, and the fourth uses 32k kernels.

In various embodiments, convolutional parameter sharing is achieved by reusing the same kernel (i.e., the same learnable operator-parameterizations of the tree nodes) across multiple spatial placements (i.e., across different (i, j) locations), similar to how CNN weights are shared across spatial locations. In some embodiments, for each output channel (tree kernel), the logic gates (or their differentiable/relaxed forms) are chosen and parameterized independently, but all placements of that kernel share those parameters.

FIG. 5 further illustrates pooling blocks coupled after one or more Conv blocks. In various embodiments, the pooling blocks are configured to perform a logical pooling operation over receptive fields, such as logical OR pooling, which aggregates activations within a pooling receptive field. In some embodiments, pooling may be implemented as a relaxed Boolean aggregation using a t-conorm or t-norm formulation; for example, logical OR pooling may be implemented using a maximum t-conorm relaxation such that, for a pooling receptive field, the pooled activation equals the maximum activation within the receptive field (i.e., max pooling as an OR relaxation).

In some embodiments, the pooling operation is configured as strided pooling, in which the stride equals the size of the pooling receptive field (e.g., a 2×2 kernel with a stride of 2), thereby defining non-overlapping pooling regions. This configuration provides computational and memory advantages: the system may store only the pooled activation and a selection index (or other selection data) indicating which activation was selected as the maximum, and during training, it may backpropagate gradients only through the selected activation(s).

In the illustrated example, each pooling block is shown with a pooling kernel size of 2×2 and a stride of 2 (e.g., “or-Pool: ks=2×2, str=2” for the first pooling block, and “P: 2×2, 2” for subsequent pooling blocks). Consistent with the above, in some embodiments, each pooling block performs logical OR pooling with a kernel size of 2×2 and a stride of 2. In one illustrative embodiment for an image-classification task (e.g., CIFAR-10), FIG. 5 shows an architecture 1000 comprising four convolutional blocks, followed by three randomly connected logic layers and a GroupSum output stage.

In some embodiments, the Conv blocks and Rand layers comprise learnable (differentiable) logic gate nodes, while the pooling layers are fixed (non-learnable) logical aggregation layers. In some embodiments, during training, the learnable logic gate nodes are implemented as probabilistic (or other differentiable) relaxations of logic gates, where each learnable node is parameterized by a softmax distribution over a set of candidate logic operators, and the node output is computed from the learned distribution. In contrast, in some embodiments, the pooling layers are implemented using fixed logical OR operations (or their continuous max t-conorm relaxations) rather than learned gate choices.

In some embodiments, the pooling blocks of FIG. 5 comprise repeating structural inductive-bias gates arranged at multiple locations within the node network. For example, where a plurality of pooling blocks are interleaved with convolutional logic gate-tree blocks, the pooling-stage nodes may form part of the second set of nodes and may use the second relaxation rather than the first relaxation used for learnable logic gate-tree nodes. In some embodiments, the repeated placement of the pooling blocks at multiple stages of the architecture imposes a spatial structural inductive bias on the node network, including a bias toward local receptive-field aggregation and spatial downsampling in a convolutional logic gate network.

In some embodiments, training of the architecture 1000 is implemented using fused compute kernels that fuse evaluation of a logic gate tree (per kernel placement) together with pooling, thereby reducing memory traffic. For example, in an embodiment with tree depth d=3 and 2×2 OR pooling, the system may evaluate four tree placements corresponding to a 2×2 pooling region, then apply a maximum t-conorm pooling operation to produce a single pooled output. In such embodiments, intermediate values (e.g., intermediate tree node outputs and/or intermediate pre-pooling outputs) may be held in registers or local storage and need not be written to memory, and the system may write only the pooled output value and an index of the pooling operation to memory, thereby reducing memory writes and overall training memory footprint. During a backward pass, the system may recompute only selected intermediate values corresponding to the selected pooling path, as needed, to propagate gradients.

In some embodiments, after the convolutional and pooling stages, the architecture 1000 includes a classification head comprising multiple regular, differentiable logic layers (Rand layers) followed by a GroupSum stage. In some embodiments, the Rand layers are “randomly connected” layers in which connectivity between nodes may be randomly constructed and held fixed, while the per-node operator choices are learned. In some embodiments, the GroupSum stage partitions output nodes into groups (e.g., 10 groups corresponding to 10 classes) and computes, for each group, a class score by aggregating (e.g., summing) the outputs of nodes in that group. In some embodiments, the resulting class scores may be used to compute a prediction (e.g., via an argmax over class scores). In hardware-oriented embodiments, the aggregation may be implemented using adders realized as logic gates to efficiently accumulate output bits into an integer score per class.

Although FIG. 5 illustrates a particular example architecture 1000, the illustrated configuration is non-limiting. For example, in various embodiments: (i) the number of convolutional blocks may be greater than or less than four; (ii) receptive field sizes may differ across blocks (e.g., 5×5 in an initial block for certain datasets); (iii) tree depth d may vary by block; (iv) pooling may be applied at some blocks but not others; (v) pooling may be OR pooling (max t-conorm), AND pooling (min t-norm), or a mixture; and/or (vi) the classification head may include additional or fewer Rand layers, different layer widths, and/or different output aggregation strategies.

Additionally, in some embodiments, one or more connectivity restrictions may be applied for convolutional tree inputs to improve performance and/or hardware routing; for example, selection of input channels (CM) for each tree may be restricted such that each tree observes only a limited number of channels (e.g., two channels) to enforce spatial comparisons within a channel and/or to reduce routing congestion in hardware implementations, although such restrictions are optional and the method is not limited thereto.

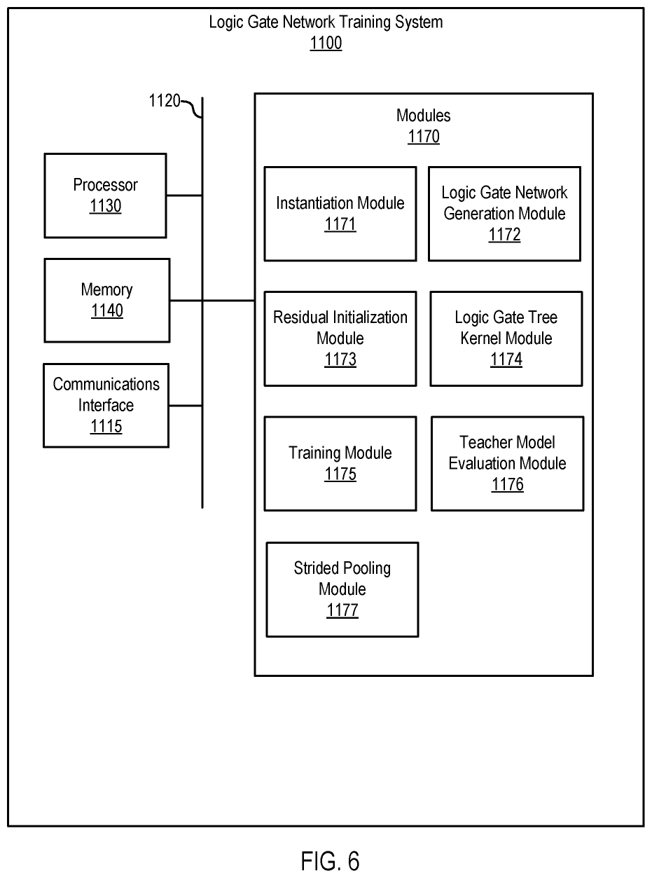

FIG. 6 illustrates an example logic gate network training system 1100 for instantiating, training, and generating (e.g., discretizing) logic gate networks for machine-learning inference tasks, according to one embodiment. In various embodiments, the logic gate network training system 1100 implements and/or orchestrates one or more of the processes described herein, including (by way of example) the residual initialization process of FIG. 4A and/or any of the processes described in any of the applications to which this application claims priority, where such processes have been previously incorporated herein by reference in their entirety.

In the illustrated embodiment, the logic gate network training system 1100 includes one or more processors 1130, a memory 1140, and a communications interface 1115. In some embodiments, the processor(s) 1130 include one or more general-purpose processors (e.g., CPUs), one or more parallel processors (e.g., GPUs), one or more accelerators (e.g., TPUs/NPUs), and/or programmable logic or custom logic usable to accelerate training or inference-related operations. The memory 1140 may include one or more non-transitory computer-readable media, such as RAM, ROM, flash memory, solid-state storage, and/or other persistent or non-persistent storage. The memory 1140 may store, among other things, training data sets, distillation data sets, input tensors, intermediate activations, pooling selection data, connection-index arrays, differentiable parameters (e.g., logits or other unnormalized scores), derived probability distributions (e.g., softmax probabilities, sigmoid probabilities, input-conditional output probabilities), gradients, learned operator selections, and fixed-network representations such as netlists and/or hardware description language (HDL) representations.

In the illustrated embodiment, the processor 1130, memory 1140, communications interface 1115, and one or more modules 1170 are communicatively coupled via one or more interconnects 1120. The interconnect 1120 may include one or more buses (e.g., a system bus), crossbars, network-on-chip interconnects, shared memory fabrics, point-to-point links, and/or other communication mechanisms that allow transfer of instructions and data among the depicted components. The communications interface 1115 may include one or more wired or wireless network interfaces (e.g., Ethernet, Wi-Fi, PCIe, or other interfaces) usable to receive training data, send trained model artifacts, access remote compute resources, access a remote teacher model service, and/or communicate with downstream synthesis or hardware deployment toolchains.

The modules 1170 are representative functional blocks and may be implemented in hardware, software, firmware, or any combination thereof. In some embodiments, one or more of the modules 1170 are implemented as instructions stored in memory 1140 and executed by one or more processors 1130. Additionally or alternatively, one or more of the modules 1170 are implemented using dedicated circuitry, accelerators, programmable logic, and/or custom logic. The boundaries between the modules 1170 are illustrative and non-limiting; in various embodiments, operations described as being performed by a particular module may be performed by a different module, combined with another module, subdivided into sub-modules, and/or distributed across multiple devices (e.g., a training system and a deployment device), without departing from the scope of the present disclosure.

The instantiation module 1171 is configured to instantiate untrained differentiable logic gate networks in memory 1140. In some embodiments, instantiation includes allocating data structures that represent a network topology (e.g., layers, trees, directed acyclic graphs, and/or other topologies), allocating and initializing differentiable parameters for nodes, and configuring operator sets for nodes (e.g., specifying the predefined set of potential logic gate operators available at each node).

In some embodiments, the instantiation module 1171 instantiates a differentiable logic gate network having a plurality of nodes arranged in a plurality of layers, where each node is parameterized by differentiable parameters corresponding to a predefined set of potential logic gate operators (e.g., including AND, OR, XOR, NAND, NOR, constants, inverters, and/or direct-connection operators). In some embodiments, the instantiation module 1171 further configures a differentiable relaxation used for training (e.g., probabilistic relaxations and/or min/max relaxations, and/or other relaxations described herein), thereby enabling gradient-based optimization.

In convolutional embodiments, the instantiation module 1171 may instantiate one or more convolutional layers in which each convolution kernel is represented as a logic gate tree kernel, and may configure architectural hyperparameters such as tree depth, number of kernels (output channels), receptive field sizes, stride/padding/dilation settings, and/or channel grouping parameters.

In pooling embodiments, the instantiation module 1171 may configure one or more pooling layers or pooling stages (including strided pooling stages), define pooling receptive fields (e.g., pooling window sizes), and allocate memory for pooling selection data (e.g., argmax/argmin indices or other selection metadata) used for training-time backpropagation.

The logic gate network generation module 1172 is configured to generate and/or define an initial (untrained) logic gate network structure and associated connectivity. In various embodiments, this includes generating a randomly connected logic gate network, generating a structured logic gate network (e.g., including convolutional blocks), and/or generating auxiliary data structures that define connectivity patterns.

For example, in some embodiments, the logic gate network generation module 1172 generates connection patterns between nodes of adjacent layers and stores connection identifiers in one or more arrays (e.g., connection-index arrays), which may then be reused during forward propagation to determine which prior-layer outputs feed each node. In convolutional embodiments, the logic gate network generation module 1172 may cooperate with the logic gate tree kernel module 1174 to define, for each kernel, a mapping from receptive-field positions and input channels to tree leaves, thereby enabling consistent parameter sharing across kernel placements.

In some embodiments, the logic gate network generation module 1172 generates multiple candidate network configurations (e.g., different random seeds, different tree structures, different operator sets, different pooling placements) and provides such configurations to the training module 1175 for training and evaluation (e.g., for architecture search, ablation studies, or model selection).

The residual initialization module 1173 is configured to perform residual initialization of a differentiable logic gate network prior to training. In some embodiments, residual initialization includes initializing differentiable parameters for at least a plurality of nodes such that an initial operator-selection probability distribution over the predefined set of potential logic gate operators assigns a highest (or greatest) probability to a feedforward logic gate operator, relative to probabilities assigned to other potential logic gate operators.

In various embodiments, the residual initialization module 1173 configures feedforward behavior without hard-wiring residual connections and without adding logic gate nodes dedicated to implementing them. In some embodiments, residual initialization is applied to substantially all learnable nodes in a network. In other embodiments, residual initialization is applied selectively (e.g., to deeper layers, specific blocks, or specific stages) to improve early signal flow and gradient propagation where vanishing gradients are more likely.

In some embodiments, the residual initialization module 1173 selects, for a node, a feedforward operator that comprises one of: (i) a direct-connection operator that outputs a first node input, (ii) a direct-connection operator that outputs a second node input, (iii) an inverter operator that outputs an inverse of the first node input, or (iv) an inverter operator that outputs an inverse of the second node input. In some embodiments, residual initialization is implemented by setting initial differentiable parameters such that (i) a feedforward operator has an initial selection probability in a range such as approximately 0.85 to 0.95 and (ii) remaining probability mass is distributed across other operators (e.g., substantially uniformly), while still enabling training to shift probability mass toward non-feedforward operators where beneficial.

In some embodiments, the residual initialization module 1173 supports multiple trainable representations of node operations. For example, the module may residual-initialize (i) a categorical operator-selection representation (e.g., softmax over 2\hat{ }{2\hat{ }k}parameters for k-input Boolean functions) by disproportionately biasing a feedforward choice such as a wire function, and/or (ii) a truth-table representation (e.g., 2\hat{ }k parameters mapped into [0,1]) by initializing the truth-table parameter vector so that discretization yields a wire or inverter function as an initial per-node operation.

The logic gate tree kernel module 1174 is configured to implement convolutional logic gate networks in which convolution kernels are represented as logic gate trees (e.g., binary trees or E-ary trees). In some embodiments, the logic gate tree kernel module 1174 generates and/or stores, for each logic gate tree kernel, (i) a tree topology defining how outputs of lower nodes feed higher nodes and (ii) a leaf-selection mapping that defines how a receptive field of an input tensor is mapped to the leaves of the tree.

In some embodiments, during forward propagation, the logic gate tree kernel module 1174 performs a convolution over an input tensor by iterating over a set of kernel placements in a domain (e.g., positions in a 2D grid) and, for each placement, selecting a set of leaf input activations from the receptive field and forward-propagating the leaf activations through the logic gate tree kernel to produce a kernel output activation. In some embodiments, differentiable parameters for nodes of a given logic gate tree kernel are shared among multiple placements, thereby implementing convolutional parameter sharing and spatial equivariance.

In some embodiments, the logic gate tree kernel module 1174 supports binary trees of depth d, where the number of leaves is 2^{d}, and/or supports non-binary (E-ary) nodes configured to receive three or more inputs. In some embodiments, the module stores and reuses connection-index arrays that define, for each leaf, an input-channel identifier and a position offset within the receptive field. In some embodiments, these arrays are generated pseudo-randomly at instantiation and thereafter held fixed across training, thereby enabling training to focus on learning operator selections and/or operator blending parameters.

The training module 1175 is configured to train differentiable logic gate networks using one or more training data sets. In various embodiments, training includes iterative training over a plurality of training iterations, where each training iteration includes forward propagation of inputs through the differentiable logic gate network, computation of a loss value, and updating differentiable parameters using a training optimization algorithm.

In some embodiments, during forward propagation, the training module 1175 computes node outputs using differentiable combinations of candidate logic operator outputs. For example, in some embodiments, each node has differentiable parameters that define (directly or indirectly) a categorical distribution over candidate logic gate operators. The training module 1175 may map differentiable parameters to a probability distribution using a softmax operation (optionally with a temperature parameter), and compute a differentiable node output as a weighted combination of the candidate operator outputs according to the probability distribution.

In some embodiments, the training module 1175 computes a loss value based on differences between network outputs and target output values (e.g., cross-entropy for classification, mean-squared error for regression, divergence-based objectives for distillation, and/or composite objectives that combine multiple loss terms). The training module 1175 may then compute gradients (e.g., by backpropagation through differentiable relaxations and through pooling operations) and update differentiable parameters using one or more optimizers (e.g., stochastic gradient descent, Adam, or other gradient-based optimization techniques).

In some embodiments, the training module 1175 coordinates with the residual initialization module 1173 (e.g., by invoking residual initialization prior to a first training iteration) and coordinates with the logic gate tree kernel module 1174 and strided pooling module 1177 during forward propagation and backpropagation in architectures that include convolutional logic gate trees and pooling blocks.

The teacher model evaluation module 1176 is configured to obtain and evaluate a teacher model for student-teacher training (distillation) embodiments. In some embodiments, the teacher model is a conventionally trained neural network (including a policy/value model for reinforcement learning), and the teacher model evaluation module 1176 evaluates the teacher model on input vectors (or input tensors) to generate teacher output values such as logits, probabilities, class distributions, action distributions, value estimates, and/or other supervision signals.

In some embodiments, the teacher model evaluation module 1176 supports multiple teacher-supervision workflows. For example, the module may (i) generate teacher outputs on-the-fly during student training (e.g., per training iteration or per batch) or (ii) precompute teacher outputs and store them in memory 1140 as a distillation data set. In some embodiments, the module applies calibration or scaling operations to teacher outputs, such as temperature scaling or logit scaling, to adjust supervision entropy and improve distillation behavior.

In some embodiments, the teacher model evaluation module 1176 obtains teacher models and/or teacher output values via the communications interface 1115 (e.g., from a remote server, a cloud service, or a distributed training environment). In other embodiments, teacher evaluation is performed locally on the same computing device used to train the student model.

The strided pooling module 1177 is configured to implement pooling operations in differentiable logic gate networks, including strided pooling operations (SPooling) that utilize min/max relaxation operations compatible with logic gate computation. In some embodiments, the strided pooling module 1177 defines pooling receptive fields (e.g., pooling windows in a spatial domain and/or across channels) and generates pooled activations by applying one or more min/max operations to activations within each receptive field.

In some embodiments, OR-pooling is implemented via a maximum operation corresponding to a maximum t-conorm relaxation of logical OR, and/or AND-pooling is implemented via a minimum operation corresponding to a minimum t-norm relaxation of logical AND. In some embodiments, the stride of the pooling operation equals the receptive field size (e.g., non-overlapping receptive fields), thereby reducing compute and memory traffic relative to pooling implementations that require overlapping windows and/or storing intermediate values for all window positions.

In some embodiments, the strided pooling module 1177 stores pooling selection data for each pooling receptive field (e.g., an index identifying the max-selected activation for OR-pooling and/or an index identifying the min-selected activation for AND-pooling). During backpropagation, the strided pooling module 1177 uses the stored pooling selection data to propagate gradients through the selected activation(s) (e.g., only through the max-selected activation for max pooling), which can reduce training-time computation and memory bandwidth. In some embodiments, the strided pooling module 1177 may be used as part of a convolutional logic gate tree network, including architectures in which pooling blocks are interleaved with tree-kernel convolutional blocks and/or classification heads.

In various embodiments, not all modules 1170 are used in every configuration. For example, teacher model evaluation module 1176 may be omitted in embodiments that train directly from ground-truth labels rather than teacher supervision; logic gate tree kernel module 1174 may be omitted in embodiments that use non-convolutional random connectivity; and strided pooling module 1177 may be omitted in embodiments that do not include pooling layers. Similarly, residual initialization module 1173 may be used alone or in combination with convolutional logic gate trees, pooling, and/or student-teacher training. Thus, FIG. 6 is intended to illustrate an example system architecture that supports multiple aspects of the present disclosure, including the four claim sets described herein, and is not intended to imply that all depicted modules must be present or utilized in all embodiments.

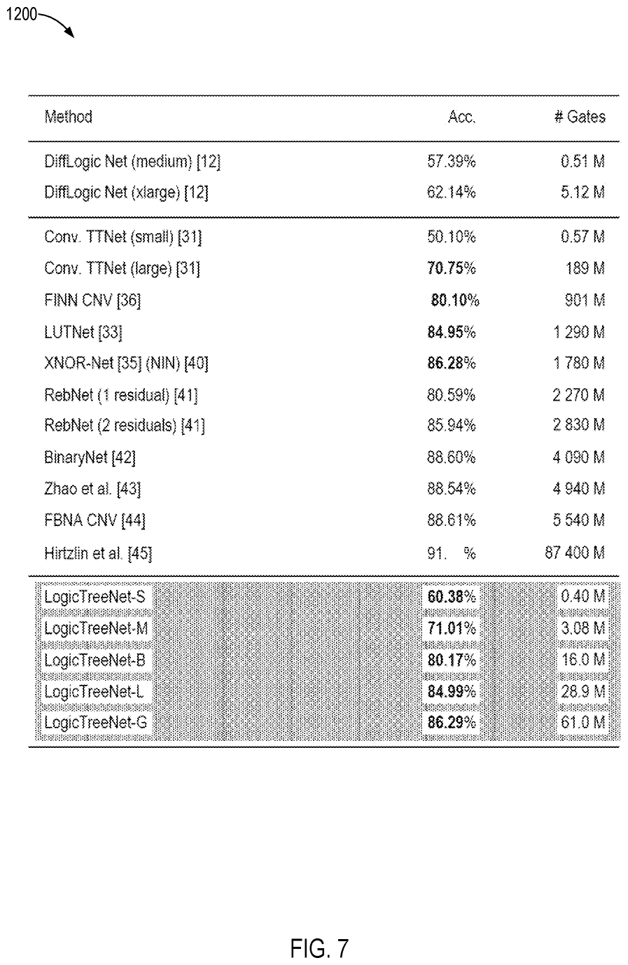

FIG. 7 illustrates an example results table 1200 comparing accuracy and gate counts for CIFAR-10 across logic gate network models and baseline models, according to one embodiment. As illustrated, the table 1200 provides a comparative performance summary for logic gate-based machine learning models on an inference task (e.g., image classification on CIFAR-10), in which each row identifies a respective model (or model configuration), and corresponding columns report (i) an accuracy metric (“Acc.”) and (ii) a logic gate complexity metric (“#Gates”). In some embodiments, the “#Gates” metric represents a number of logic gates and/or binary logic operations in a discretized (fixed) logic gate network implementation, and is usable as a proxy for hardware cost and efficiency, including, for example, transistor count and chip area for an ASIC implementation and/or resource utilization on an FPGA implementation. In the illustrated example, the table 1200 includes results for various baseline models. The table 1200 further includes multiple example embodiments of convolutional logic gate-tree networks (“LogicTreeNet”) scaled to different sizes. As illustrated, the LogicTreeNet architectures may be scaled to reach targeted accuracy levels while providing substantial reductions in logic gate count relative to other approaches at comparable accuracy levels, thereby enabling more efficient deployment of the trained inference model as logic circuitry (e.g., reduced area and/or improved performance and power efficiency on ASICs and/or FPGAs).

The following example illustrates the use of learned information on a per-switching-event basis. In an illustrative embodiment, an unrolled FINN CNV binary neural network may utilize approximately 120 million bits per full-image inference, with between 20 million and 120 million of those bits corresponding to machine-learned functional information. Such a network may, on average, during full-image inference, comprise between 200 million and 400 million gate-switching events. Accordingly, the network may utilize, on average, between 0.05 and 0.6 bits of machine-learned functional information per switching event of the physical logic gates in transforming the input to the output. In contrast, in some embodiments, a quality-wise comparable or substantially quality-wise identical neural network comprising directly optimized logic circuitry may overall comprise around 16 million gates. A full inference for such a network may comprise, on average, 3 million to 8 million gate switches. Accordingly, such a network may utilize, on average, between 2.5 and 40 bits of machine-learned functional information per switching event of the physical logic gates in transforming the input to the output. In some embodiments, for example, where neural networks are convolutional, when considering an information count for utilization across multiple distinct consumption events of the same information, machine-learned functional information may be counted repeatedly despite being shared, corresponding to the number of consumption events when unrolled.

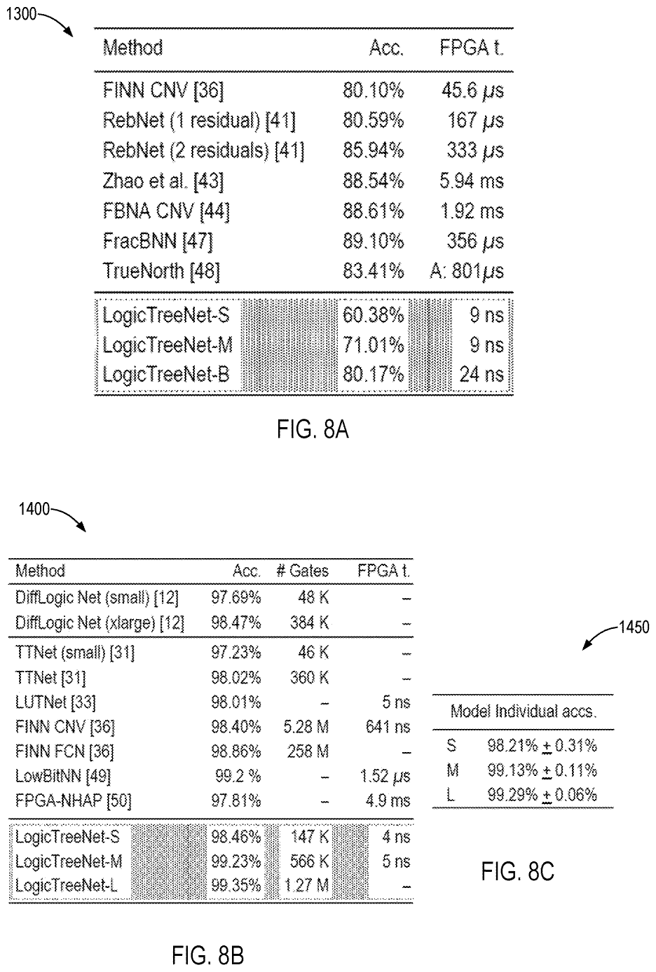

FIG. 8A provides an example comparative results table 1300 for a representative image-classification task (e.g., CIFAR-10) that is included to demonstrate that a trained, discretized logic gate-based model can be realized as a fixed logic circuit and evaluated with extremely low inference latency on a field-programmable gate array (FPGA), while achieving competitive predictive performance relative to prior approaches. FIG. 8A shows that, once the differentiable training process has selected concrete logic operators and the model has been discretized into a fixed logic gate network, the resulting implementation can shift the practical performance bottleneck away from conventional weight-fetch and arithmetic costs and toward I/O transfer considerations, thereby enabling orders-of-magnitude improvements in throughput and/or latency for inference workloads. FIG. 8A further supports the proposition that additional acceleration (and/or power reduction) may be achievable through fixed-silicon implementations (e.g., application-specific integrated circuits), because the trained model is representable as a circuit description suitable for synthesis and hardware realization.

FIG. 8B provides an example results table 1400 for a representative handwritten-digit classification task (e.g., MNIST) to illustrate the intended “accuracy-per-logic-cost” and “accuracy-per-latency” benefits of the disclosed logic gate-tree-based architectures and training techniques. As illustrated, the logic gate-based models produced by differentiable training and subsequent discretization can simultaneously (i) achieve high classification accuracy, (ii) remain compact in terms of logic resources (e.g., gate count as a proxy for hardware cost), and (iii) execute with very low end-to-end inference time on FPGA hardware. The disclosed approach is not merely theoretically compatible with hardware deployment; it can also deliver high-quality inference with logic-native execution characteristics.

FIG. 8C provides an example variability (repeatability) table 1450 that demonstrates the robustness of the disclosed training and discretization workflow across multiple independently trained model instances. For example, despite the use of randomized factors that may be present in some implementations (e.g., random initialization, randomized connection selection, randomized minibatch order, or other stochastic training effects), the resulting discretized logic gate networks can exhibit stable and reproducible inference accuracy with comparatively small run-to-run variation. This supports practical deployment scenarios in which consistent model quality is important (including hardware deployment), and it further supports embodiments in which multiple instances of a trained model (or multiple independently trained models) may be deployed, replicated, or synthesized with predictable behavior and predictable performance characteristics.

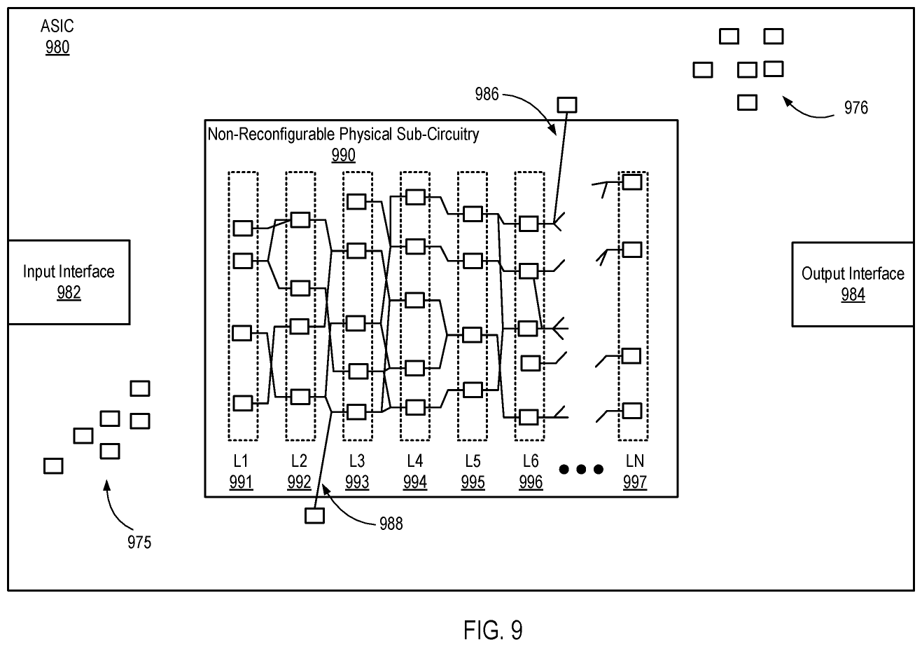

FIG. 9 illustrates an example application-specific integrated circuit (ASIC) 980 that performs neural-network inference using deeply layered non-reconfigurably physically implemented sub-circuitry 990 arranged between an input interface 982 of the ASIC 980 and an output interface 984 of the ASIC 980, according to one embodiment. The input interface 982 may be configured to receive one or more inputs, which may be represented as binary signals, encoded feature vectors, multi-bit digital values, or other digital representations for inference processing. The figure is schematic and not necessarily drawn to scale, and the illustrated gates and connections represent a larger fixed inference structure.

In some embodiments, a majority of operations of the neural network (e.g., inference) are implemented by the sub-circuitry 990 itself. Nevertheless, in many embodiments, the sub-circuitry 990 may be a selected component of the overall ASIC 980 and may not constitute all the logic circuitry of the ASIC 980 or all circuitry participating in a neural network implementation. For example, the ASIC 980 may further include additional circuit elements 975 and 976 outside of the selected sub-circuitry 990. These additional circuit elements 975 and 976 may implement one or more additional portions of the neural network and/or one or more support functions. Examples of such additional circuit elements 975 and 976 include, but are not limited to, input conditioning, buffering, fan-out, fan-in, output conditioning, interface functions, synchronization, pipelining, residual or skip-path functions, control functions, and/or other logic or storage functions. Accordingly, a “sub-circuitry” as used herein may comprise a proper subset of a larger neural network implementation and may be analyzed independently for characteristics such as number of physical logic gates, number of layers, machine-learned functional information density, aperiodicity, adder percentage, or other properties. Inputs received at the input interface 982 may pass through, be modified by, and/or be otherwise processed by other circuitry elements prior to being received by the inputs of the sub-circuitry. Similarly, output signals of the sub-circuitry 990 may be transmitted to, accumulated by, and/or otherwise processed by other circuitry of the ASIC 980 prior to being received at the output interface 984. In some embodiments, less than 10%, less than 1%, or even less than 0.01% of operations of the neural network (e.g., inference) are implemented by the sub-circuitry 990 itself. In some embodiments, the ASIC may comprise many respective sub-circuitries.

In the illustrated embodiment, the non-reconfigurable physical sub-circuitry 990 comprises a plurality of physical logic gates arranged in successive layers. By way of example, the illustrated layered topology includes a first layer 991, a second layer 992, a third layer 993, a fourth layer 994, a fifth layer 995, a sixth layer 996, and an Nth layer 997. The depiction of layers 991-997 is illustrative, and in various embodiments, the sub-circuitry 990 includes at least seven layers, at least twelve layers, at least twenty-three layers, or more than twenty-three layers. In some embodiments, every path from any sub-circuitry input to any sub-circuitry output traverses at least N layers of the sub-circuitry 990, where N is an integer greater than 6, and in some embodiments, greater than 23. Although only a limited number of representative gate symbols are shown for clarity, the sub-circuitry 990 may include, in some specific example embodiments, but not by way of limitation, at least 1,000 physical logic gates, at least 147,000 physical logic gates arranged in at least 12 layers, or at least 16,000,000 physical logic gates arranged in at least 23 layers. Any number of physical logic gates in excess of 1,000 may be arranged in any number of layers in excess of six. Embodiments are contemplated in which tens of millions of gates (e.g., 20 million gates, 80 million gates, 1 billion gates, 10 billion gates, and more) are arranged in a topology with thousands of layers, which is possible using the residual initialization techniques and algorithms described herein.

The sub-circuitry 990 physically embodies machine-learned functional information in a fixed circuit structure, rather than in memory used to store learned parameters for run-time retrieval. In particular, the machine-learned functional information may be embodied in a combination of logic-gate selections implemented by respective physical logic gates and fixed connections therebetween. In various embodiments, the physical logic gates of the sub-circuitry 990 implement learned Boolean functions, learned lookup-table-like functions, inversion functions, pass-through functions, multiplexing functions, and/or other learned discrete logic functions, and the fixed connections (e.g., wires, traces, omitted wires or traces, etc.) among layers 991, 992, 993, 994, 995, 996, and 997 further embody learned structure of the neural network. In some embodiments, the machine-learned functional information embodied by the sub-circuitry 990 is at least one-half bit per physical logic gate on average. In further embodiments, the density is at least 1 bit per physical logic gate, at least 2 bits per physical logic gate, at least 4 bits per physical logic gate, or at least 10 bits per physical logic gate. In some embodiments, such information density is accounted for based on information physically represented by gate selections, constants, input selections, and/or hardwired inter-layer or inter-node connections of the sub-circuitry 990.

During inference, signals are propagated from inputs (not shown) of the sub-circuitry 990 to outputs (not shown) of the sub-circuitry 990. The signals are propagated through the fixed layered topology of the sub-circuitry 990, including through the first layer 991, the second layer 992, the third layer 993, the fourth layer 994, the fifth layer 995, the sixth layer 996, and the Nth layer 997. In various embodiments, the layers and other circuit components of a physical ASIC are placed and routed, as understood by a person skilled in the art, and the illustrated block diagram of the ASIC 980 does not necessarily reflect the physical layout of a respective sub-circuitry. Instead, the depicted block diagram of the ASIC 980 illustrates the layers from a left-to-right information-flow perspective. For example, in a physical ASIC, the physical logic gates may not be neatly arranged in clearly separated layers, but may instead be placed and routed according to a physical permutation that maintains a respective information flow.

In various embodiments, the fixed structure of the sub-circuitry 990 is such that, during neural network inference operations, an average of at least 0.125 bits per physical logic gate of the sub-circuitry 990 is affectively used during a single cycle to form the output based on the input. In various embodiments, the sub-circuitry 990 is configured such that, during inference, an average of at least 1 bit of machine-learned functional information per switching event of the physical logic gates is utilized, and in some embodiments an average of at least 2 bits of machine-learned functional information per switching event of the physical logic gates is utilized in transforming the input to the output.

In some embodiments, at least 50% of the physical logic gates of the sub-circuitry 990 are arranged in an aperiodic block pattern, rather than in periodically repeating functional blocks. In some embodiments, no more than 5% of the sub-circuitry 990 comprises adder circuitry. In such embodiments, the majority of the inference function is implemented using logic-gate selections and fixed connections rather than arithmetic accumulation structures.

In some embodiments, the logic circuitry of the ASIC 980 further includes one or more flip-flops and/or latches, while the machine-learned functional information remains primarily embodied in the fixed logic-gate selections and fixed connections of the sub-circuitry 990 rather than in a memory. In some embodiments, the sub-circuitry 990 is generated from a machine-learning flow in which a neural network is trained, logic selections and/or connections are determined based on the training, the resulting structure is discretized into fixed logic, and the fixed logic is synthesized and physically implemented as the ASIC 980. Thus, the illustrated ASIC 980 provides a hardware implementation of a neural network in which the learned function is materially embodied in the non-reconfigurable physical structure of the sub-circuitry 990.

As further illustrated, a selected sub-circuitry 990 may have one or more boundary crossing connections that do not necessarily define counted inputs or counted outputs of that selected sub-circuitry 990. For example, wire 988 may provide an additional incoming signal from a circuit element outside of the selected sub-circuitry 990 to an internal location of the selected sub-circuitry 990, such as between the layer L2 992 and the layer L3 993. Similarly, wire 986 may provide an additional outgoing signal from a location within the selected sub-circuitry 990 (e.g., from a location downstream of the layer L6 996) to a circuit element outside of the selected sub-circuitry 990. In some embodiments, such additional incoming and/or outgoing wires are auxiliary, branch, skip, control, feedback, residual, fan-out, fan-in, or otherwise supplementary connections. The presence of such connections does not require that those wires be treated as counted inputs or counted outputs of the selected sub-circuitry.

In some embodiments, the number of layers of a selected sub-circuitry is determined with respect to one or more designated inputs and one or more designated outputs of that selected sub-circuitry. For example, “at least N layers between an input and an output” may mean that there exists at least one designated signal path from at least one designated input of the selected sub-circuitry to at least one designated output of the selected sub-circuitry that traverses at least N successive layers or stages of physical logic gates. In other embodiments, “at least N layers between all inputs and all outputs” may mean that each designated path from each designated input of the selected sub-circuitry to each designated output of the selected sub-circuitry traverses at least N successive layers or stages of physical logic gates. Accordingly, the layer count may be defined on an “at least one input to at least one output” basis or on an “all designated inputs to all designated outputs” basis.

Thus, for purposes of counting layers, the selected sub-circuitry 990 may be defined using one or more designated inputs entering the selected sub-circuitry at an upstream side (e.g., before layer L1 991) and one or more designated outputs leaving the selected sub-circuitry at a downstream side (e.g., after layer LN 997), even though additional boundary-crossing wires, such as 988 and 986, may also enter or leave the selected sub-circuitry at intermediate locations. In some embodiments, an auxiliary incoming wire does not, by itself, reduce the counted number of layers between a designated input and a designated output. Moreover, an auxiliary outgoing wire such as 986 does not, by itself, terminate the counted path. Accordingly, a selected sub-circuitry may include additional incoming wires and additional outgoing wires while still being characterized as having at least N layers between a designated input and a designated output, or at least N layers between all designated inputs and all designated outputs, depending on how the selected sub-circuitry is defined for the particular analysis.

In some embodiments, a sub-circuitry may (e.g., by effect) utilize learned information retrieved from memories, but that information may not be counted as part of the machine-learned functional information physically embodied in the physical logic gates when it is not physically embodied in the physical logic gates. In some embodiments, whether a flip-flop element is placed or omitted between two circuit elements of a sub-circuitry may comprise machine-learned functional information. For example, in some embodiments, learned information may include whether to use a connection that connects a node to an activation of a current cycle or to an activation of a past cycle, which, in physical terms, may be represented as a wire or a flip-flop, respectively.

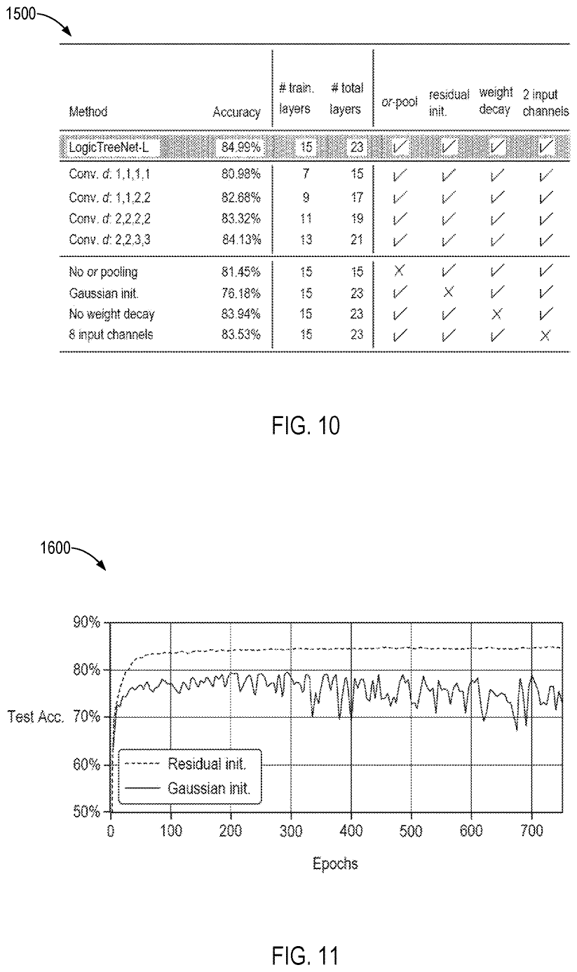

FIG. 10 illustrates an example ablation results table 1500 for architectural and training choices in convolutional logic gate networks, according to one embodiment. The example ablation study table 1500 shows how architectural and training choices affect the performance of convolutional logic gate-tree networks (e.g., a “LogicTreeNet-L” configuration) and, in particular, how increasing convolutional/tree depth can improve accuracy while maintaining convolutional parameter sharing. In the illustrated example, a baseline LogicTreeNet-L configuration achieves about 84.99% accuracy with 15 trainable layers and 23 total logical layers when logical OR pooling (“or-pool”), residual initialization, weight decay, and a two-input-channel restriction per tree are enabled; shallower convolutional configurations (e.g., “Conv. d: 1,1,1,1” up through “Conv. d: 2,2,3,3”) show progressively increasing accuracies (e.g., about 80.98% to 84.13%) as depth increases. The table 1500 further illustrates that omitting OR pooling can reduce accuracy (e.g., to about 81.45%), omitting residual initialization can substantially reduce accuracy (e.g., Gaussian initialization at about 76.18%), and other choices such as disabling weight decay or allowing additional input channels can also reduce accuracy; these results are consistent with the notion that using logic gate trees, residual initialization, and OR pooling affect the performance of convolutional LGNs, and that restricting each convolutional tree kernel to fewer input channels can encourage within-channel spatial comparisons and improve hardware routing/locality in some embodiments.

FIG. 11 illustrates an example plot 1600 comparing training behavior under residual initialization versus Gaussian initialization, according to one embodiment. The example training-trajectory plot 1600 compares test accuracy across training epochs for an embodiment with residual initialization versus a conventional Gaussian initialization, illustrating that residual initialization can stabilize training and enable convergence in deeper logic gate-based architectures. In some embodiments, residual initialization is performed by initializing each logic gate node's differentiable operator-selection parameters such that a feedforward operator (e.g., a wire/pass-through choice such as “A,” and in some cases symmetrically also “B,” “1-A,” or “1-B”) is assigned a dominant initial probability (e.g., about 90%) while remaining candidate operators share the remaining probability mass (e.g., about 0.67% each across 16 operators), which can be achieved by setting one parameter (e.g., z3=5) larger than the others (e.g., zi=0 for i≠3) prior to applying a softmax mapping. As illustrated, without such residual initialization, the training can become unstable and may not converge, whereas residual initialization can prevent loss of information and vanishing gradients in deeper networks while allowing training to replace feedforward behaviors with other learned logic operations when beneficial, without hard-wiring additive residual connections or requiring additional dedicated residual gates.

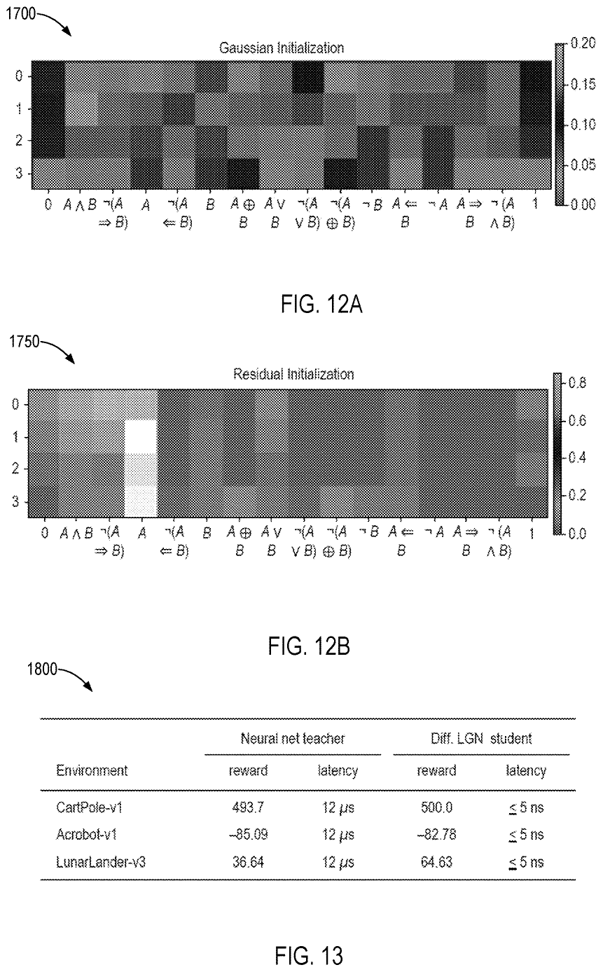

FIG. 12A illustrates, for a trained logic gate network (e.g., an MNIST model), an example heat-map distribution 1700 of logic gate-operator selections resulting from Gaussian initialization, where rows correspond to layers and columns correspond to logic gate operator choices, and the heat-map intensity indicates the relative prevalence (or probability mass/selection frequency) of each operator choice in each layer. In this example, the Gaussian-initialized model exhibits a comparatively diffuse distribution across the candidate operator set (e.g., across a 16-operator family including constants, pass-throughs, inverters, and two-input Boolean operators), which is consistent with an initialization that does not intentionally bias the network toward feedforwarding (“wire-like”) behaviors at the start of training.

FIG. 12B illustrates, for a trained logic gate network (e.g., an MNIST model), an example heat-map distribution 1750 of logic gate-operator selections resulting from residual initialization, again with rows corresponding to layers and columns corresponding to logic gate operators. In the illustrated example, residual initialization produces a pronounced concentration of operator selections (or selection probability mass) in a feedforward operator (e.g., “A”), reflecting a favorable inductive bias that can (i) improve trainability/stability of deeper logic gate networks and (ii) be reduced as needed by learning and/or subsequent logic simplification, as some gates transition away from pure feedforward behavior to implement more complex Boolean operations that improve task performance.

FIG. 13 illustrates an example results table 1800 comparing reinforcement-learning rewards and inference latencies for a neural-network teacher and a logic gate-network student, according to one embodiment. The table 1800 compares a conventionally trained neural-network teacher to a differentiable logic gate-network student across multiple environments (e.g., CartPole-v1, Acrobot-v1, and LunarLander-v3). In some embodiments, the teacher is trained using a reinforcement-learning algorithm (e.g., PPO), the teacher is evaluated to produce a data set of input observations and corresponding teacher predictions (e.g., action-probability distributions), and the student logic gate network is trained by minimizing a divergence between student outputs and teacher outputs (e.g., a Kullback-Leibler divergence) to transfer teacher behavior to a logic gate-based student suitable for ultra-low-latency inference. The illustrated results show that the student can match or exceed the teacher reward while dramatically reducing inference latency (e.g., teacher latencies on the order of ~12 μs versus student latencies on the order of ≤5 ns in the table 1800), thereby evidencing embodiments in which logic gate-network inference can be implemented in extremely small latency budgets (e.g., a single FPGA clock cycle or equivalent hardware-logic evaluation window) while maintaining task performance.

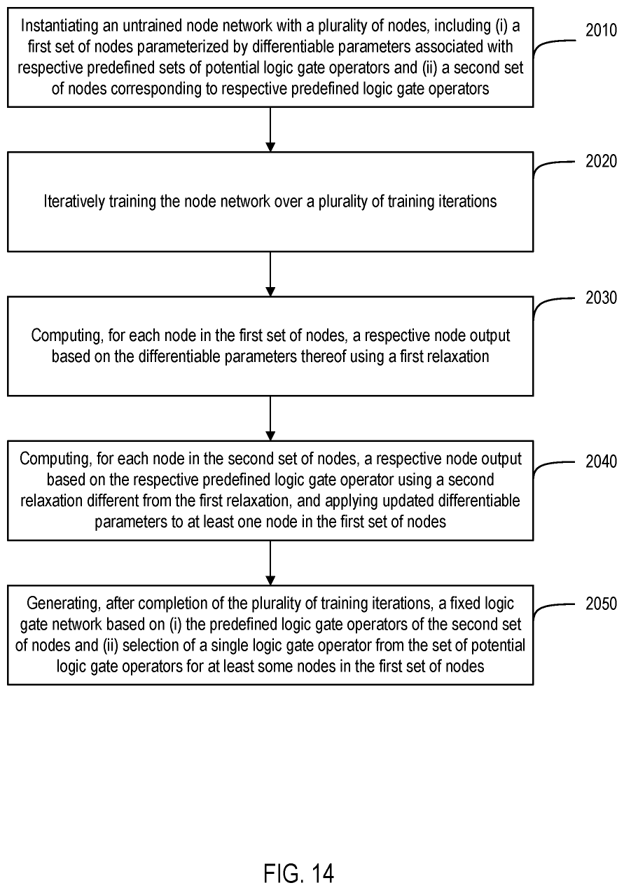

FIG. 14 illustrates an example process for training a node network using heterogeneous relaxations, according to one embodiment. In various embodiments, the process is performed by a computing system comprising one or more processors and a memory that stores instructions that, when executed, cause the computing system to instantiate an untrained node network comprising a plurality of nodes, including a first set of nodes and a second set of nodes. In some embodiments, each node in the first set is parameterized by a set of differentiable parameters associated with a respective predefined set of potential logic gate operators, while each node in the second set corresponds to a respective predefined logic gate operator. In some embodiments, the first set comprises learnable nodes and the second set comprises predefined nodes that represent a fixed or partially fixed structure within the node network.

At step 2010, the computing system instantiates the untrained node network. In some embodiments, instantiation includes allocating data structures representing the node network topology, allocating and initializing differentiable parameters for the first set of nodes, and associating the first set of nodes with respective predefined sets of potential logic gate operators. In some embodiments, the second set of nodes is instantiated as nodes corresponding to respective predefined logic gate operators, such that outputs of the second set are not determined by selecting among multiple candidate logic gate operators using differentiable parameters of the type used for the first set. At step 2020, the computing system iteratively trains the node network over a plurality of training iterations, as described herein.

At step 2030, the computing system computes, for each node in the first set of nodes, a respective node output based on the differentiable parameters of that node using a first relaxation. In some embodiments, the first relaxation is a relaxation for selecting among the predefined set of potential logic gate operators associated with the respective node, including embodiments in which the first relaxation facilitates subsequent selection of a single logic gate operator from the set. At step 2040, the computing system computes, for each node in the second set of nodes, a respective node output based on the respective predefined logic gate operator using a second relaxation different from the first relaxation. More specifically, the second relaxation is different from the first relaxation beyond the fact that the first relaxation uses differentiable parameters for selecting a single logic gate operator from the set of potential logic gate operators.

For example, in some embodiments, the first relaxation is probabilistic, continuous-non-linear, stochastic-sampling-based, Yager-based, or another differentiable relaxation, while the second relaxation is min/max-based, Hamacher-based, continuous, or another relaxation suitable for nodes corresponding to predefined logic gate operators. In some embodiments, the second relaxation is used to impose structural inductive bias in the node network.

For example, in some embodiments, in the context of convolutions, it may be favorable to use pooling operations from the second set of nodes using the second relaxation. In other words, in some embodiments, the second relaxation may be from a different family of relaxations compared to the first relaxation (e.g., probabilistic vs. min/max based relaxations). In some embodiments, one family of relaxations is advantageous from a computational perspective, while the other relaxation is advantageous from a learning dynamics perspective, motivating, in various embodiments, the use of two different relaxation types for trainable and non-trainable relaxations.

For example, in some embodiments (e.g., in some contexts of sequential models, time-series models, and language models), structure can provide improved performance. For instance, logic gate operators can connect different time-steps or cycles of the circuit, thereby providing a “bridge” across memory states (e.g., flip-flops)- and maintaining information flow. In various embodiments, it may improve the network to keep this “bridge” with a non-trainable “foundation” that provides the desired functionality, while preventing the ability to change the choice of logic-gate operator. Experimental evidence has shown that, in some embodiments, between trainable nodes and non-trainable nodes, different types of relaxations each offer distinct advantages. In some embodiments, this may be analogous to transformer models, which use predefined computational operations (e.g., attention) and different families of operations (e.g., softmax, inner product between activations) compared to the trainable part (e.g., activated matrix multiplication) of the model. In some other embodiments, the structural inductive bias is used to provide residual connections within the network(s).

At step 2050, after completion of the plurality of training iterations, the computing system generates a fixed logic gate network based on (i) the predefined logic gate operators of the second set of nodes and (ii) selection of a single logic gate operator from the set of potential logic gate operators for at least some nodes in the first set of nodes. In some embodiments, the fixed logic gate network is representable as a logical expression, circuit description, netlist, and/or hardware description language representation, and may be deployed in software, programmable logic, and/or fixed-silicon hardware. Although FIG. 14 illustrates a particular ordering of steps 2010-2050, in various embodiments, one or more steps may be subdivided, reordered, repeated, performed in parallel, and/or supplemented with additional operations.

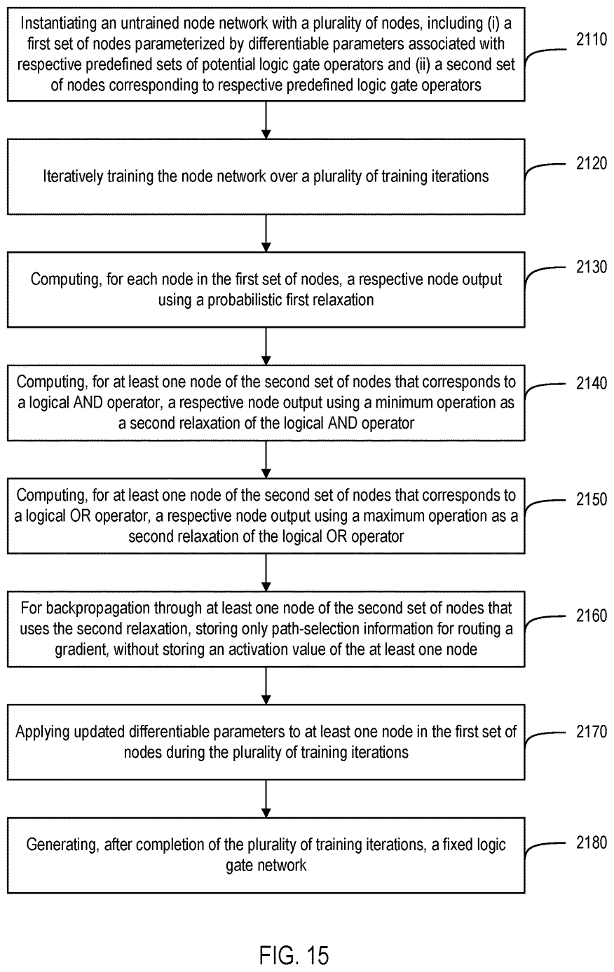

FIG. 15 illustrates an example process for training a node network using a first relaxation for a first set of nodes and a second relaxation for a second set of nodes, according to a more specific example embodiment. In various embodiments, the process further illustrates example embodiments in which the first relaxation is probabilistic and the second relaxation uses a minimum operation and/or a maximum operation for respective predefined logic gate operators.

At step 2110, the computing system instantiates an untrained node network comprising a plurality of nodes, including (i) a first set of nodes parameterized by differentiable parameters associated with respective predefined sets of potential logic gate operators and (ii) a second set of nodes corresponding to respective predefined logic gate operators. At step 2120, the computing system iteratively trains the node network over a plurality of training iterations. At step 2130, the computing system computes, for each node in the first set of nodes, a respective node output using a probabilistic first relaxation. In some embodiments, the probabilistic first relaxation comprises probabilities corresponding to the respective logic gate operators of the predefined set of potential logic gate operators, based on the differentiable parameters, and the inputs to a respective node of the first set are input activation probabilities between 0 and 1.

At step 2140, for at least one node of the second set of nodes that corresponds to a specific logical operator (e.g., a logical AND operator), the computing system computes a respective node output using a minimum operation as a second relaxation of the logical AND operator (per the specific example, but not by way of limitation). At step 2150, for at least one node of the second set of nodes that corresponds to a logical OR operator (by way of example, and not limitation), the computing system computes a respective node output using a maximum operation as a second relaxation of the logical OR operator (again, per the specific example, but not by way of limitation). In some embodiments, the second relaxation is used for nodes that provide structural inductive bias in the node network, including spatial pooling nodes, temporal-connection nodes, residual-activation-combination nodes, or other predefined nodes. In some embodiments, the second relaxation differs from the first relaxation (beyond the fact that the first relaxation uses differentiable parameters to select a single logic gate operator from the set of potential logic gate operators) and may reduce memory consumption during training relative to using the first relaxation for all nodes.

As illustrated at step 2160, in some specific examples, for backpropagation through at least one node in the second set of nodes that uses the second relaxation, the computing system stores only path-selection information for routing a gradient, without storing the activation value of that node. In some embodiments, at least two nodes of the first set are connected to one node of the second set, the node of the second set receives the outputs of the at least two nodes of the first set, and for backpropagation a gradient is routed through only one path of the node of the second set such that the gradient is not backpropagated through all of the at least two nodes of the first set. In some embodiments, this path-selection-information-only approach reduces memory usage and computational overhead during training by avoiding storage and/or reuse of full activation values for the second-set nodes.

At step 2170, the computing system applies updated differentiable parameters to at least one node in the first set of nodes during the plurality of training iterations. At step 2180, after completing the plurality of training iterations, the computing system generates a fixed logic gate network. In some embodiments, the fixed logic gate network is based on (i) predefined logic gate operators of the second set of nodes and (ii) selection of single logic gate operators from predefined sets of potential logic gate operators for at least some nodes in the first set based on the differentiable parameters thereof. Although FIG. 15 illustrates a particular sequence of steps 2110-2180, in various embodiments, one or more steps may be combined, omitted, reordered, repeated, and/or performed concurrently.

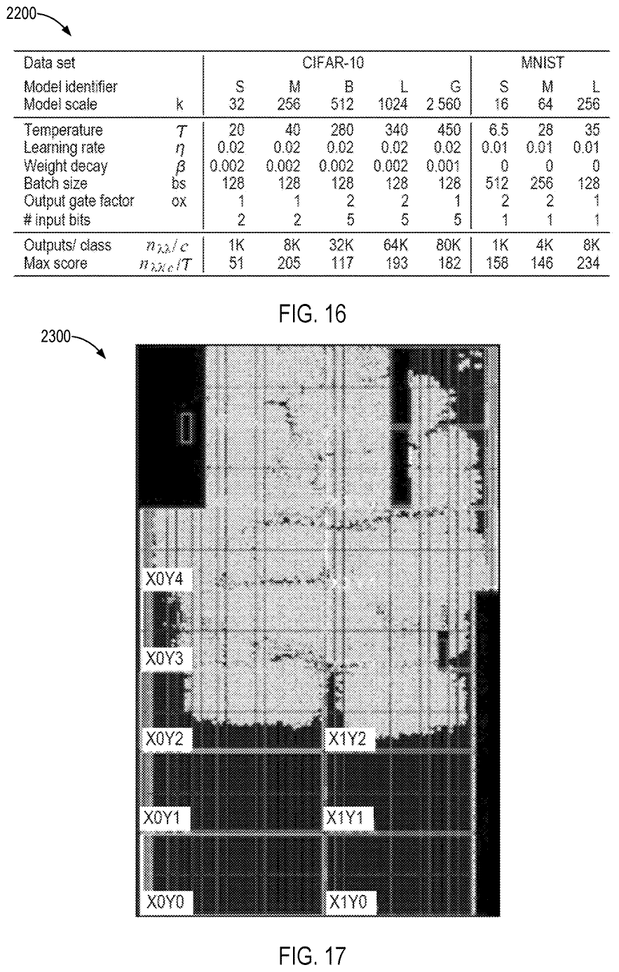

FIG. 16 is a hyperparameter summary table 2200 that lists example training configurations used to train differentiable logic gate network models on image-classification tasks, including CIFAR-10 and MNIST. In the illustrated embodiment, the table 2200 is organized by model identifiers that correspond to different model scales (e.g., CIFAR-10: S, M, B, L, G; MNIST: S, M, L) and reports, for each model scale, a corresponding width parameter (k) and example training hyperparameters including a temperature (τ), learning rate (η), weight decay (β), batch size (bs), and an output-gate factor (oₓ). The table 2200 further lists example input-representation settings (e.g., a number of input bits), an outputs-per-class setting (nₒᵤₜ/c), and an associated maximum attainable class score derived from the outputs-per-class setting and the temperature (e.g., nₒᵤₜ/c divided by r), with the attainable class-score range noted as spanning from 0 up to the maximum class score. In various embodiments, the configurations of FIG. 16 provide non-limiting examples of hyperparameter selections and output-representation scaling suitable for training and evaluating logic-gate-based models across different model sizes and datasets.

FIG. 17 illustrates an example hardware placement 2300 of a trained logic gate network implementing an MNIST inference model (e.g., model “M”) on a field-programmable gate array (FPGA) (e.g., a Xilinx XC7Z045 FPGA), in which the discretized logic gate network is mapped into spatially distributed resources of the FPGA fabric for hardware inference. In some embodiments, to facilitate routable placement and reduce routing congestion, the system may select and/or constrain internal connections of the logic gate network that are recombined at a stage of output-gate accumulation (akin to grouped convolution), while maintaining accuracy given the inherent sparsity of logic gate networks.

In various embodiments, the discretized node network is implemented in hardware using either combinational logic, sequential logic, or a combination thereof. In some embodiments, the discretized node network is unrolled such that each discretized node (or at least a selected set of nodes) corresponds to a respective hardware logic instance and the network is evaluated combinationally (e.g., within a clock cycle subject to timing closure). In other embodiments, to reduce area, resource utilization, or routing congestion, the implementation is time-multiplexed such that a hardware instance (or a subset of hardware instances) implementing one or more discretized node functions is reused across multiple evaluation phases (e.g., across multiple layers, time steps, and/or spatial placements), thereby trading off throughput and/or latency for reduced hardware resource usage.

In some embodiments, utilization of the machine-learned functional information embodied in the sub-circuitry is input-dependent rather than parameterization time-multiplexed, such that the portions of the learned logic that contribute to a given output depend on the applied input during that evaluation. In some embodiments, the circuit utilizes, on average, at least a threshold amount of machine-learned functional information per switching event of the physical logic gates in transforming the input to the output.

In some embodiments, input time-multiplexing is facilitated using storage elements including flip-flops (registers) that store intermediate values and/or pipeline stages, together with multiplexers and control logic that select inputs to a reused node-function circuit over time. For example, in a convolutional node network in which a kernel circuit (e.g., a logic-gate-tree kernel) is applied at a plurality of kernel placements, the kernel circuit may be replicated for parallel evaluation at multiple placements (unrolling), or the kernel circuit may be reused by time-multiplexing the circuit between placements such that different placements are evaluated in different clock cycles while sharing the same kernel logic resources. In certain embodiments, sliding-window buffering (e.g., shift registers, line buffers, or block RAM) supplies receptive-field inputs to the time-multiplexed kernel circuit, and flip-flops store intermediate node outputs and/or partial results to support pipelined evaluation and timing closure for a target FPGA and/or ASIC implementation. In some embodiments, the discretized node network is implemented in hardware as a combinational logic expression, partitioned into pipeline stages using registers, flip-flops, or latches, e.g., to increase throughput or mitigate metastability. It is appreciated that input time-multiplexing and parameterization time-multiplexing are distinct concepts. In input time-multiplexing (without parameterization time-multiplexing), the same parameterization is applied to multiple inputs by the same circuitry at different times. In parameterization time-multiplexing, different parameters are applied by the same circuitry at different times. In parameterization time-multiplexing (without input time-multiplexing), different parameters may be applied to the same inputs by the same circuitry at different times.

In various embodiments, the non-reconfigurably physically implemented sub-circuitry may span a wide range of scales and depths. By way of example and without limitation, a hardware implementation may include at least 1000 physical logic gates arranged in at least 7 layers between an input and an output. In other embodiments, the sub-circuitry comprises at least 147,000 physical logic gates arranged in at least 12 layers. In still another example embodiment, the sub-circuitry comprises at least 16 million physical logic gates arranged in at least 23 layers. (See, e.g., FIGS. 8-10) More generally, the sub-circuitry may include at least N layers between all inputs and all outputs, where N is any integer greater than 6. In some embodiments, N is an integer greater than 23. These examples are non-limiting and illustrate that the disclosed techniques are applicable to relatively small, intermediate, and very large fixed logic implementations of learned neural-network functionality.

As described herein, tens of millions of gates are possible, and the number of layers may be significantly increased using, for example, the residual initialization techniques described herein. By increasing the strength of the residual initialization, more layers can be achieved. The degree of bias may be increased by increasing the logit magnitude, increasing the coefficient bias, increasing the truth-table sign-pattern magnitude, increasing the fraction of nodes initialized as residual, or otherwise increasing the initial dominance of residual behavior. In various embodiments, various biasing strengths for the residual initialization are used to facilitate training neural networks having more than 6 layers, including neural networks with 50, 100, 250, or even 1000+ layers.

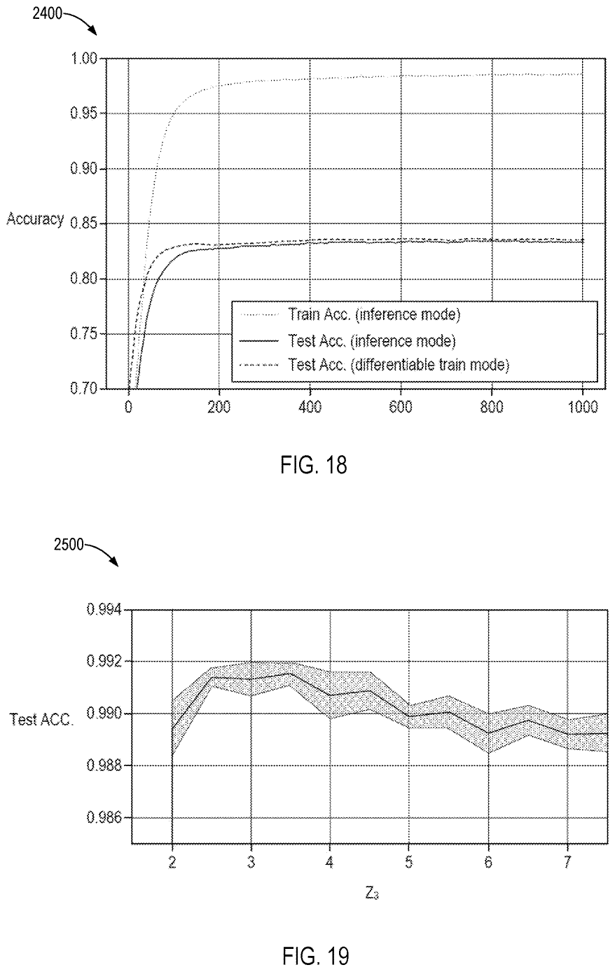

FIG. 18 illustrates an example training and test accuracy plot 2400 (e.g., for a convolutional logic gate network trained on CIFAR-10) that compares (i) training accuracy in an inference (hard) mode, (ii) test accuracy in the inference (hard) mode, and (iii) test accuracy in a differentiable training mode, as a function of training progress/steps. FIG. 18 further illustrates that the resulting discretization error (i.e., the difference between inference-mode and differentiable-mode accuracy) is very small during late training, indicating that the operator-selection distributions converge to discrete choices as training progresses. In contrast, during early training, the discretization error may be larger because the model first learns a “smooth,” differentiable network with higher uncertainty in individual gate choices, so discretization causes larger changes and may negatively affect accuracy.

FIG. 19 illustrates a plot 2500 of an example sensitivity (ablation) study for a residual-initialization hyperparameter Z3. In the illustrated embodiment, Z3 controls the strength of the bias that an untrained differentiable logic gate network is initialized with toward feedforward behavior. In particular, Z3 may correspond to (or be used to set) an initial unnormalized score (e.g., a logit) for a feedforward logic gate operator (e.g., a direct-connection operator “A” that outputs one node input), relative to initial unnormalized scores for other candidate logic gate operators in a predefined set. The horizontal axis corresponds to Z3, and the vertical axis corresponds to test accuracy (Test ACC.) for a trained model (e.g., an MNIST classification model). The curves on the plot 2500 represent test accuracy obtained for different Z3 settings (e.g., in increments of about 0.5), and the curve and/or surrounding band represent the average and variability across a plurality of training runs. As illustrated, selecting Z3 to provide sufficiently strong residual initialization (e.g., Z3 at or above a threshold such as about 2) yields stable training and high test accuracy, whereas Z3 that is too small may fail to sufficiently bias the initial operator-selection distributions toward feedforward behavior, leading to unstable training and/or poor accuracy.

In some embodiments, Z3 is selected based on characteristics of the target architecture and/or training regimen. For example, deeper and/or larger models may require stronger residual initialization (i.e., a larger Z3) to preserve information flow and gradient propagation during early training, whereas shallower models and/or longer training regimens may tolerate, or even prefer, smaller Z3.

FIG. 20 illustrates a table 2600 with an example operator set for a two-input differentiable logic gate node, enumerating a plurality of candidate logic gate operators (e.g., sixteen operators corresponding to the sixteen possible Boolean functions of two inputs). In the illustrated embodiment, the table 2600 includes (i) an identifier (ID) for each operator, (ii) an operator name and/or Boolean form, (iii) a corresponding real-valued (continuous) relaxation formula, and (iv) a truth table indication (e.g., outputs for inputs 00, 01, 10, and 11). In some embodiments, the “real-valued” formulas correspond to probabilistic or fuzzy-logic relaxations in which node input activations A and B are treated as real values (e.g., probabilities) in [0,1], thereby enabling differentiability during training.

In some embodiments, the two-input candidate operators of FIG. 20 are represented in the discretized form as lookup-table (LUT) entries (truth tables) and/or as compact integer identifiers. For example, in a two-input case with inputs A and B, the truth table may be ordered as input patterns (A,B)=00, 01, 10, 11, yielding outputs (t00, t01, t10, t11). In one implementation, an operator identifier ID in the range 0-15 is computed as: ID=t00+2 t01+4 t10+8 t11. In such embodiments, storing the selected operator for a node may include storing the ID and/or storing the corresponding 4-bit truth-table vector, and evaluating the node in the discretized network may include using the ID as a LUT index.

Under the above encoding, the single-input residual operators (i.e., operators that depend on only one input) correspond to the following IDs: NOT A has truth table (1,1,0,0) and ID=3; NOT B has truth table (1,0,1,0) and ID=5; B has truth table (0,1,0,1) and ID=10; and A has truth table (0,0,1,1) and ID=12. Accordingly, in certain embodiments, residual initialization comprises biasing the initial trainable parameters so that, prior to training, a disproportionate fraction of two-input nodes would be discretized to one of IDs 3, 5, 10, or 12 (e.g., ID=12 to implement a “wire A” pass-through), while training may subsequently cause at least some nodes to transition to other IDs that functionally depend on both inputs.

In various embodiments, the principles described with respect to the two-input operator set of FIG. 20 are extensible to multi-input nodes having k inputs, where k≥3. For a k-input node, the set of candidate discrete operations may include any subset (including all) of the 2\hat{ }(2\hat{ }k) Boolean functions of k Boolean inputs, and a discretized form of such a node may be represented as a lookup table having 2\hat{ }k input patterns and a corresponding 2\hat{ }k-bit output vector. For example, for a three-input node (k=3), there are 2\hat{ }(2\hat{ }3)=256 possible three-input Boolean operators, and the set of candidate node functions may include all 256 such operators. In this three-input case, the set of residual operators (i.e., operators that functionally depend on only a single input) includes at least six operators, namely the identity and inversion of each input (A, NOT A, B, NOT B, C, NOT C), and residual initialization may comprise biasing a disproportionate fraction of three-input nodes toward one or more such residual operators at initialization. More generally, for k-input nodes, the set of residual operators may include pass-through and inverter operators for each respective input, and different subsets of nodes may be residually initialized to different residual operators (e.g., a first subset initialized to pass through a first input and a second subset initialized to pass through a second input).

This disclosure has been made with reference to various exemplary embodiments, including the best mode. However, those skilled in the art will recognize that changes and modifications may be made to the exemplary embodiments without departing from the scope of the present disclosure. While the principles of this disclosure have been shown in various embodiments, many modifications of structure, arrangements, proportions, elements, materials, mathematical representations, combinations, and permutations of features, optional components, optional steps, and optional methods may be adapted for a specific environment and/or operating requirements without departing from the principles and scope of this disclosure. These and other changes or modifications, and all possible permutations and combinations of examples and embodiments disclosed, are intended to be included within the scope of the present disclosure.

This disclosure is to be regarded in an illustrative rather than a restrictive sense, and all such modifications are intended to be included within the scope thereof. Likewise, benefits, other advantages, and solutions to problems have been described with regard to various embodiments. However, benefits, advantages, solutions to problems, and any element(s) that may cause any benefit, advantage, or solution to occur or become more pronounced are not to be construed as a critical, required, or essential feature or element. Indeed, even inferior or non-optimized versions of the described embodiments are intended to be included within the scope of this disclosure. The scope of this disclosure includes the numbered claims below, and all claims and clauses in the applications to which this application claims priority, including all feasible combinations thereof.

What is claimed is:

1. An application-specific integrated circuit (ASIC), comprising:
logic circuitry that is an implementation of a neural network, the logic circuitry including non-reconfigurably physically implemented sub-circuitry, the sub-circuitry having:
at least 1000 physical logic gates arranged in at least 7 layers between an input and an output,
wherein the sub-circuitry embodies, on average, machine-learned functional information of at least one-half bit per physical logic gate, and
wherein the machine-learned functional information is physically embodied in a combination of logic gate selections and connections therebetween, rather than in a memory.

2. The application-specific integrated circuit of claim 1, wherein the sub-circuitry is configured such that, during neural network inference operations, utilization of the machine-learned functional information is input-dependent, rather than parameterization time-multiplexed.

3. The application-specific integrated circuit of claim 1, wherein the sub-circuitry is configured to, during neural network inference operations, utilize, on average, at least 1 bit of the machine-learned functional information per switching event of the physical logic gates in transforming the input to the output.

4. The application-specific integrated circuit of claim 1, wherein the sub-circuitry is configured to, during neural network inference operations, utilize an average of at least 2 bits of machine-learned functional information per switching event of the physical logic gates in transforming the input to the output.

5. The application-specific integrated circuit of claim 1, wherein the sub-circuitry comprising the at least 1000 physical logic gates arranged in the at least 7 layers is configured to implement a majority of operations of the neural network.

6. The application-specific integrated circuit of claim 1, wherein at least 50% of the physical logic gates of the sub-circuitry are arranged in an aperiodic block pattern, rather than in periodically repeating functional blocks.

7. The application-specific integrated circuit of claim 1, wherein an average of at least 0.125 bits per physical logic gate of the sub-circuitry are affectively used during a single cycle of the sub-circuitry to form the output based on the input.

8. The application-specific integrated circuit of claim 1, wherein the sub-circuitry comprises at least 147 thousand gates arranged in at least 12 layers.

9. The application-specific integrated circuit of claim 1, wherein the sub-circuitry comprises at least 16 million gates arranged in at least 23 layers.

10. The application-specific integrated circuit of claim 1, wherein the sub-circuitry includes at least N layers between all inputs and all outputs, wherein N is an integer value greater than 6.

11. The application-specific integrated circuit of claim 1, wherein the sub-circuitry includes at least N layers between all inputs and all outputs, wherein N is an integer value greater than 23.

12. The application-specific integrated circuit of claim 1, wherein the sub-circuitry comprises at least 100 layers between an input and an output.

13. The application-specific integrated circuit of claim 1, wherein at least 50% of the machine-learned function information is embodied in the structure of the logic that directly participates in the inference computation.

14. The application-specific integrated circuit of claim 1, wherein the machine-learned functional information embodied by the sub-circuitry comprises at least 1 bit per physical logic gate.

15. The application-specific integrated circuit of claim 1, wherein the machine-learned functional information embodied by the sub-circuitry comprises at least 2 bits per physical logic gate, and wherein an average of at least 0.25 bits per physical logic gate of the sub-circuitry are affectively used during the single cycle of the sub-circuitry to form the output based on the input.

16. The application-specific integrated circuit of claim 1, wherein the machine-learned functional information embodied by the sub-circuitry comprises at least 4 bits per physical logic gate.

17. The application-specific integrated circuit of claim 1, wherein the machine-learned functional information embodied by the sub-circuitry comprises at least 10 bits per physical logic gate.

18. The application-specific integrated circuit of claim 1, wherein no more than 5% of the sub-circuitry comprises adder circuitry.

19. The application-specific integrated circuit of claim 1, wherein the logic circuitry further comprises one or more of: flip-flops and latches.

20. The application-specific integrated circuit of claim 1, wherein the sub-circuitry comprises at least 2,000 gates arranged in at least 23 layers between an input and an output,
wherein the machine-learned functional information embodied by the sub-circuitry comprises at least 1 bit per physical logic gate,
wherein either (i) none of the sub-circuitry comprises adder circuitry or (ii) less than 35% of the sub-circuitry comprises adder circuitry, and
wherein the sub-circuitry is configured to, during neural network inference operations, utilize, on average, at least 1 bit of the machine-learned functional information per switching event of the physical logic gates in transforming the input to the output.

21. An application-specific integrated circuit (ASIC), comprising:
logic circuitry that is an implementation of a neural network, the logic circuitry including non-reconfigurably physically implemented sub-circuitry, the sub-circuitry having:
at least 1000 physical logic gates arranged in at least 23 layers between an input and an output,
wherein the sub-circuitry physically embodies machine-learned functional information in a combination of logic gate selections and connections therebetween, rather than in a memory, and
wherein the sub-circuitry is configured to, during neural network inference operations, utilize, on average, at least 1 bit of the machine-learned functional information per switching event of the physical logic gates in transforming the input to the output.

22. A method for performing inference, comprising:
operating an application-specific integrated circuit to perform an inference operation, wherein the ASIC comprises:
logic circuitry that is an implementation of a neural network, the logic circuitry including non-reconfigurably physically implemented sub-circuitry, the sub-circuitry having:
at least 1000 physical logic gates arranged in at least 7 layers between an input and an output,
wherein the sub-circuitry embodies machine-learned functional information of at least one-half bit per physical logic gate, and
wherein the machine-learned functional information is physically embodied in a combination of logic gate selections and connections therebetween, rather than in a memory.
